(19) United States
(12) Patent Application Publication
(10) Pub. No.: US 2026/0181872 A1
(43) Pub. Date: Jun. 25, 2026

(54) SEMICONDUCTOR DEVICE AND METHOD FOR FABRICATING THE SAME

(71) Applicant: SK hynix Inc., Gyeonggi-do (KR)

(72) Inventor: Dong Il SONG, Gyeonggi-do (KR)

(21) Appl. No.: 19/248,489

(22) Filed: Jun. 25, 2025

(30) Foreign Application Priority Data
Dec. 19, 2024 (KR) 10-2024-0191107

(51) Int. Cl. H10B 12/00

(52) U.S. Cl. CPC H10B 12/482; H10B 12/03; H10B 12/05

(57) ABSTRACT

A semiconductor device including high-integrated memory cells and a method for fabricating the semiconductor device is provided. The semiconductor device includes nano sheets arranged in a vertical arrangement and a horizontal arrangement and spaced apart from a surface of a substrate; horizontal conductive lines horizontally oriented and disposed to surround the nano sheets arranged in the horizontal arrangement; vertical conductive lines coupled in common to the nano sheets arranged in the vertical arrangement and respectively coupled to the nano sheets arranged in the horizontal arrangement; supporters disposed between the vertical conductive lines to support the vertical conductive lines; and an array isolation layer including bridge preventing portions disposed between bottom portions of the vertical conductive lines and the surface of the substrate.

### CROSS-REFERENCE TO RELATED APPLICATIONS

The present application claims priority under 35 U.S.C 119(a) to Korean Patent Application No. 10-2024-0191107, filed on Dec. 19, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, there have been increasing demands for larger capacity and greater miniaturization of memory devices. In order to cope with these demands, three-dimensional (3D) memory devices that include stacked memory cells have been proposed.

### SUMMARY

Embodiments of the present disclosure are directed to a semiconductor device including high-integrated memory cells, and a method for fabricating the semiconductor device.

In accordance with an embodiment of the present disclosure, a semiconductor device may include: nano sheets arranged in a vertical arrangement and a horizontal arrangement and spaced apart from a surface of a substrate; horizontal conductive lines horizontally oriented and disposed to surround the nano sheets arranged in the horizontal arrangement; vertical conductive lines coupled in common to the nano sheets arranged in the vertical arrangement and respectively coupled to the nano sheets arranged in the horizontal arrangement; supporters disposed between the vertical conductive lines to support the vertical conductive lines; and an array isolation layer including bridge preventing portions disposed between bottom portions of the vertical conductive lines and the surface of the substrate.

In accordance with an embodiment of the present disclosure, a method for fabricating a semiconductor device may include: forming a mold stack including mold layers vertically stacked over a substrate; forming sacrificial isolation layers in the mold stack; forming a linear opening penetrating the mold stack and extending into the substrate; replacing a portion of the sacrificial isolation layers with supporters through the linear opening; trimming first portions of the mold layers of the mold stack to form narrow sheets; forming sacrificial pocket layers on one side of the narrow sheets; forming a sacrificial protection layer on a bottom surface of the linear opening; removing the sacrificial pocket layers; forming a vertical conductive line coupled in common to one side of the narrow sheets; selectively removing the sacrificial protection layer; and forming an array isolation layer including bridge preventing portions that fill the linear opening and are disposed between a bottom portion of the vertical conductive line and a surface of the substrate. The sacrificial protection layer includes a selective epitaxial growth layer. The forming of the sacrificial protection layer includes selectively and epitaxially growing a silicon germanium layer on the bottom surface of the linear opening. The vertical conductive line is formed to be self-aligned with the supporters. The array isolation layer further includes an air gap adjacent to the vertical conductive line. The method may further include, after the forming of the array isolation layer: horizontally recessing second portions of the mold layers to form fan-shaped sheets; and forming data storage elements each respectively coupled to the fan-shaped sheets. The method may further include, after the forming of the narrow sheets: removing the sacrificial isolation layers to expose the narrow sheets; forming a first spacer horizontally extending to surround a part of the exposed narrow sheets; forming a horizontal conductive line that is adjacent to the first spacer and horizontally extends to surround the narrow sheets; and forming a second spacer that is adjacent to the horizontal conductive line and horizontally extends to surround the narrow sheets. The method may further include, before the forming of the vertical conductive line: selectively growing a contact node on one side of the narrow sheets; and forming an ohmic contact layer on the contact node. The contact node includes a selective epitaxial growth layer.

In accordance with an embodiment of the present disclosure, a semiconductor device may include: a first vertical conductive line spaced apart from a surface of a substrate; a second vertical conductive line horizontally spaced apart from the first vertical conductive line; first nano sheets arranged in a vertical arrangement coupled in common to the first vertical conductive line; second nano sheets arranged in a vertical arrangement coupled in common to the second vertical conductive line; a first horizontal conductive line horizontally oriented and disposed to surround the first nano sheets; a second horizontal conductive line horizontally oriented and disposed to surround the second nano sheets; supporters disposed to support the first and second vertical conductive lines; and an array isolation layer disposed between the first vertical conductive line and the second vertical conductive line, the array isolation layer including bridge preventing portions disposed between bottom portions of the first and second vertical conductive lines and the surface of the substrate.

In accordance with an embodiment of the present disclosure, a method for fabricating a semiconductor device may include: forming a mold stack including mold layers vertically stacked over a substrate; forming sacrificial isolation layers in the mold stack; forming a linear opening penetrating the mold stack and extending into the substrate; replacing a portion of the sacrificial isolation layers with supporters through the linear opening; trimming first portions of the mold layers of the mold stack to form narrow sheets; forming sacrificial pocket layers on one side of the narrow sheets; forming a sacrificial protection layer on a bottom surface of the linear opening; removing the sacrificial pocket layers; forming a dummy ohmic contact layer on the sacrificial protection layer; forming a vertical conductive line coupled in common to one side of the narrow sheets; forming a vertical spacer on the vertical conductive line; cutting the dummy ohmic contact layer and the sacrificial protection layer using the vertical spacer as a barrier; selectively removing the sacrificial protection layer and forming a bottom trench; trimming a bottom surface of the bottom trench; and forming an array isolation layer including bridge preventing portions that fill the linear opening and the bottom trench and are disposed between a bottom portion of the vertical conductive line and a surface of the substrate.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2A is a schematic perspective view illustrating a semiconductor device in accordance with an embodiment of the present disclosure.

FIG. 2B is a partial perspective view illustrating a first spacer illustrated in FIG. 2A.

FIG. 2C is a partial perspective view illustrating a second spacer illustrated in FIG. 2A.

FIG. 3 is a schematic perspective view illustrating a semiconductor device in accordance with an embodiment of the present disclosure.

FIG. 4A is a schematic plan view illustrating a semiconductor device in accordance with an embodiment of the present disclosure.

FIG. 4B is a schematic cross-sectional view of the semiconductor device taken along line A-A′ illustrated in FIG. 4A.

FIG. 4C is a schematic cross-sectional view of the semiconductor device taken along line A1-A1′ illustrated in FIG. 4A.

FIG. 4D is a schematic cross-sectional view of the semiconductor device taken along line B-B′ illustrated in FIG. 4A.

FIGS. 5A to 28B illustrate various views of a semiconductor device formed utilizing a method for fabricating the semiconductor device in accordance with an embodiment of the present disclosure.

FIG. 29 is a schematic cross-sectional view of a semiconductor device in accordance with an embodiment of the present disclosure.

FIGS. 30 to 34 illustrate various views of the semiconductor device formed utilizing a method for fabricating the semiconductor device illustrated in FIG. 29.

FIGS. 35A and 35B are schematic cross-sectional views of a semiconductor device in accordance with embodiments of the present disclosure.

FIGS. 36A and 36B illustrate various views illustrating a stack assembly in accordance with embodiments of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

The following embodiments provide three-dimensional memory cells, in which memory cells are vertically stacked to increase memory cell density and reduce parasitic capacitance.

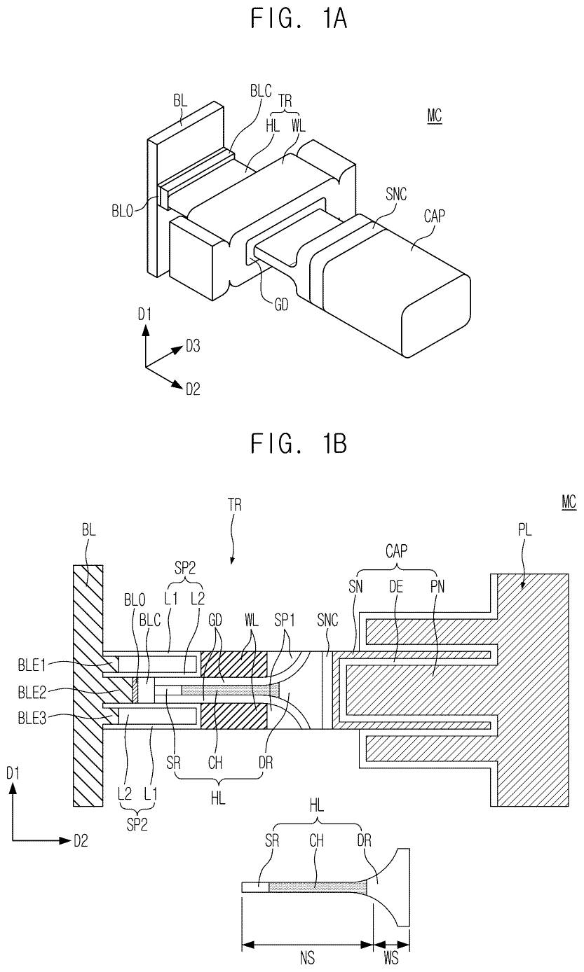

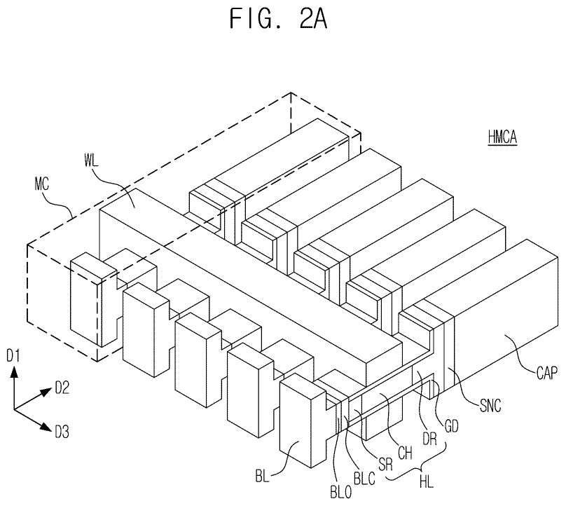

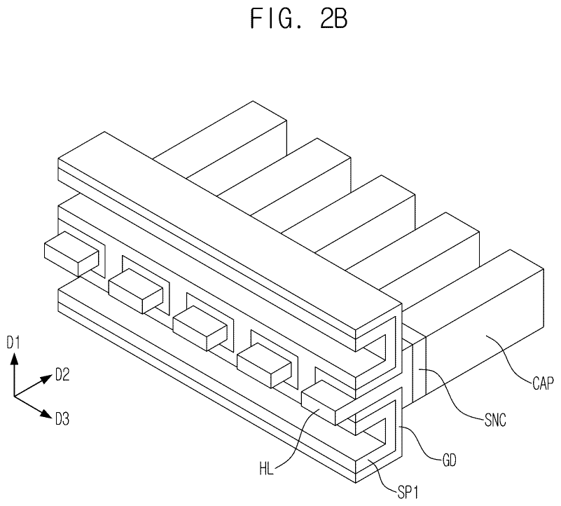

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR has a function of controlling voltage or current supply to the data storage element CAP during a data write operation and a data read operation performed on the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. The switching element TR may also be referred to as a “nano sheet transistor”, a “cell transistor”, an “access element” or a “selection element”. The second conductive line WL may be referred to as a “horizontal gate electrode” or a “horizontal word line”.

The nano sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. A height of the second doped region DR in the first direction D1 may be greater than a height of the channel CH in the first direction D1. A length of the second doped region DR in the second direction D2 may be less than a length of the channel CH in the second direction D2. The lengths of the first doped region SR, the channel CH and the second doped region DR in the third direction D3 may be equal to one another.

The nano sheet HL may include a first sheet region NS and a second sheet region WS that are horizontally disposed in the second direction D2. The second sheet region WS may extend from the first sheet region NS. The second sheet region WS may have a thickness that gradually increases in the second direction D2 from the first sheet region NS toward the data storage element CAP between the first sheet region NS and the data storage element CAP. An average vertical height or thickness of the second sheet region WS in the first direction D1 may be greater than an average vertical height or thickness of the first sheet region NS. Hereinafter, the first sheet region NS is referred to as a “narrow sheet”, and the second sheet region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS and one side of the second doped region DR, which contact the data storage element CAP, may each have a flat side shape.

A horizontal length of the wide sheet WS in the second direction D2 may be less than a horizontal length of the narrow sheet NS. The narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, MoS₂, WS₂, or MoSe₂.

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with an impurity having the same conductivity type. Each of the first doped region SR and the second doped region DR may be doped with an N-type conductive impurity or a P-type conductive impurity. The first doped region SR and the second doped region DR may each include at least one impurity selected from among arsenic (As), phosphorus (P), boron (B), indium (In), and combinations thereof. The first doped region SR may be coupled to the first conductive line BL, and the second doped region DR may be coupled to the data storage element CAP. The first and second doped regions SR and DR may be referred to as “first and second source/drain regions”.

The nano sheet HL may be horizontally oriented in the second direction D2 from the first conductive line BL.

The second conductive line WL may have a gate-all-around (GAA) structure. For example, the second conductive line WL may surround the nano sheet HL and extend in the third direction D3. The nano sheet dielectric layer GD may be formed between the nano sheet HL and the second conductive line WL. The nano sheet dielectric layer GD may surround the nano sheet HL. The second conductive line WL may surround the nano sheet HL on the nano sheet dielectric layer GD.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or less, and the P-type work function material may have a high work function of approximately 4.5 eV or greater. The second conductive line WL may include a stack of a low work function material and a high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxynitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by a thermal oxidation process of a semiconductive material. In some embodiments, the nano sheet dielectric layer GD may be formed by deposition and oxidation processes of a nano sheet dielectric material.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first electrode SN may have a three-dimensional structure, which may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces and cylindrical outer surfaces of the first electrode SN.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum nitride (MoN), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium nitride/titanium silicon nitride (TiN/TiSiN) stack, a titanium silicon nitride/titanium nitride/tungsten (TiSiN/TiN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Because the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a ZHZAZHZA (ZrO₂/HfO₂/ZrO₂/Al₂O₃/ZrO₂/HfO₂/ZrO₂/Al₂O₃) stack, a ZHZAZHZAT (ZrO₂/HfO₂/ZrO₂/Al₂O₃/ZrO₂/HfO₂/ZrO₂/Al₂O₃/TiO₂) stack, a HZHZ (HfO₂/ZrO₂/HfO₂/ZrO₂) stack, or an AHZAZHA (Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material. The dielectric layer DE may have a laminated structure in which a plurality of high-k materials and a plurality of high band gap materials are stacked or an intermixed structure in which a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, the data storage element CAP may further include a plurality of interface control layers to alleviate leakage current. The interface control layers may each include titanium oxide (TiO₂), tantalum oxide (Ta₂O₅), niobium oxide (Nb₂O₅), niobium nitride (NbN), niobium oxynitride (NbON), or a combination thereof. A first interface control layer may be formed between the first electrode SN and the dielectric layer DE, and a second interface control layer may be formed between the dielectric layer DE and the second electrode PN. The first interface control layer and the second interface control layer may be the same material or different materials.

For example, a structure in which the first interface control layer, the dielectric layer DE and the second interface control layer are sequentially stacked may include a NZHZAZHZATN (Nb₂O₅/ZrO₂/HfO₂/ZrO₂/Al₂O₃/ZrO₂/HfO₂/ZrO₂/Al₂O₃/TiO₂/Nb₂O₅) stack.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. A height of the first contact node BLC in the first direction D1 may be less than a height of the second contact node SNC in the first direction D1. The height of the first contact node BLC in the first direction D1 may be greater than a height of the channel CH in the first direction D1. The first and second contact nodes BLC and SNC may each include polysilicon doped with an N-type impurity, for example, phosphorus-doped polysilicon or arsenic-doped polysilicon.

In some embodiments, the second contact node SNC may be selectively grown from the wide sheet WS of the nano sheet HL. The second contact node SNC may be formed by selective epitaxial growth (SEG). For example, the second contact node SNC may be a silicon epitaxial layer formed by the SEG. The second contact node SNC may be a doped silicon epitaxial layer, for example, a silicon epitaxial layer doped with an N-type impurity.

In some embodiments, the first contact node BLC may also be selectively grown from the narrow sheet NS of the nano sheet HL. The first contact node BLC may be formed by selective epitaxial growth (SEG). For example, the first contact node BLC may be a silicon epitaxial layer formed by the SEG. The first contact node BLC may be a doped silicon epitaxial layer, for example, a silicon epitaxial layer doped with an N-type impurity.

The first contact node BLC may be a narrow sheet-side contact node, and the second contact node SNC may be a wide sheet-side contact node.

The nano sheet HL may include a first edge and a second edge. The first edge may refer to a portion of the first doped region SR electrically coupled to the first conductive line BL, and the second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide such as titanium silicide or molybdenum silicide.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include silicon oxide, silicon nitride, or a combination thereof. The first spacer SP1 may include silicon nitride. The first liner L1 of the second spacer SP2 may be silicon nitride, whereas the second liner L2 of the second spacer SP2 may be silicon oxide. The second liner L2 may partially fill an inner space of the first liner L1.

The first conductive line BL may include a plurality of horizontal extension portions BLE1, BLE2, and BLE3. The horizontal extension portions BLE1, BLE2, and BLE3 may extend in the second direction D2. The horizontal extension portions may include an inner horizontal extension portion BLE2 and outer horizontal extension portions BLE1 and BLE3. The inner horizontal extension portion BLE2 of the first conductive line BL may extend to be disposed in a gap between the first liners L1 vertically adjacent to each other. Accordingly, the inner horizontal extension portion BLE2 of the first conductive line BL may be electrically coupled to the ohmic contact layer BLO.

The outer horizontal extension portions BLE1 and BLE3 of the first conductive line BL may extend to be disposed in one side of the second spacer SP2. Accordingly, the outer horizontal extension portions BLE1 and BLE3 of the first conductive line BL may contact the second liner L2 of the second spacer SP2.

From another perspective, the memory cell MC may have a 1T-1C structure, where 1T may refer to one switching element TR and 1C may refer to one data storage element CAP. When the memory cell MC is a DRAM cell having the 1T-1C structure, 1T may refer to one cell transistor and 1C may refer to one capacitor. Accordingly, a gate of the cell transistor may be a word line, a first source/drain region of the cell transistor may be coupled to a bit line, and a second source/drain region of the cell transistor may be coupled to the capacitor. Herein, the bit line may correspond to the first conductive line BL illustrated in FIGS. 1A and 1B, the word line may correspond to the second conductive line WL illustrated in FIGS. 1A and 1B, and the capacitor may correspond to the data storage element CAP illustrated in FIGS. 1A and 1B. In addition, the first source/drain region may correspond to the first doped region SR illustrated in FIGS. 1A and 1B, and the second source/drain region may correspond to the second doped region DR illustrated in FIGS. 1A and 1B.

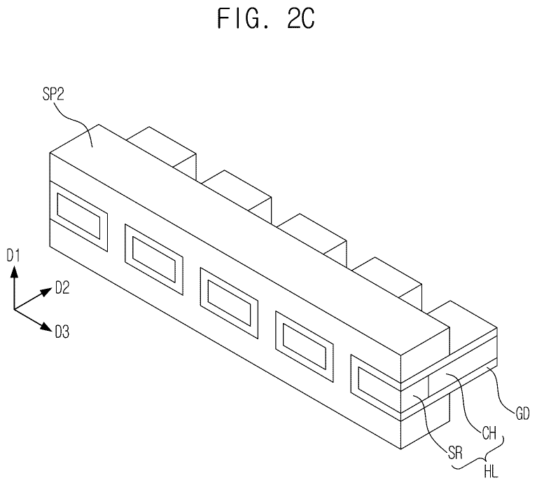

FIG. 2A is a schematic view illustrating a semiconductor device in accordance with an embodiment of the present disclosure. FIG. 2B is a partial perspective view further illustrating a first spacer SP1 illustrated in FIG. 2A. FIG. 2C is a partial perspective view further illustrating a second spacer SP2 illustrated in FIG. 2A.

FIG. 2A illustrates a horizontal array HMCA in which a plurality of memory cells MC are horizontally arranged. Each of the memory cells illustrated in FIG. 2A may be the memory cell MC described above with reference to FIGS. 1A and 1B.

Referring to FIGS. 1A, 1B, and 2A to 2C, the horizontal array HMCA may include a horizontal arrangement of the memory cells MC. The memory cells MC of the horizontal array HMCA may be horizontally spaced apart in a third direction D3. Each of the memory cells MC of the horizontal array HMCA may be coupled to a different one of first conductive lines BL. The horizontal array HMCA may include a horizontal arrangement of a plurality of first conductive lines BL. The memory cells MC of the horizontal array HMCA may share one second conductive line WL. Each of the memory cells MC may include a first conductive line BL, a nano sheet HL, and a data storage element CAP. The nano sheet HL may include a first doped region SR, a channel CH, and a second doped region DR. A first contact node BLC and an ohmic contact layer BLO may be formed between the first doped region SR of the nano sheet HL and the first conductive line BL. A second contact node SNC may be formed between the second doped region DR of the nano sheet HL and the data storage element CAP. The nano sheet HL may be surrounded by a nano sheet dielectric layer GD. The second conductive line WL may extend in the third direction D3 while surrounding the channels CH of the nano sheets HL disposed at the same horizontal level on the nano sheet dielectric layer GD.

The horizontal array HMCA may further include the first spacer SP1 and the second spacer SP2 as described above with reference to FIG. 1B.

Referring back to FIGS. 1B and 2B, the first spacer SP1 may extend in the third direction D3 while surrounding portions of the nano sheets HL disposed at the same horizontal level, that is, the second doped regions DR. The first spacer SP1 may include protruding portions surrounding the second doped regions DR of the nano sheets HL. The protruding portions of the first spacer SP1 may be merged with each other and extend in the third direction D3. The first spacer SP1 may have an integral structure of extending in a first direction D1. The protruding portions of the first spacer SP1 may each have a cup shape, and cross-sections of the protruding portions may each have a an open shape (for example, a “C” shape, a “U” shape, or a shape with right angles “[”).

Referring back to FIGS. 1B and 2C, the second spacer SP2 may extend in the third direction D3 while surrounding portions of the nano sheets HL, that is, the first doped regions SR. Portions of the second spacer SP2 may partially overlap with the channels CH.

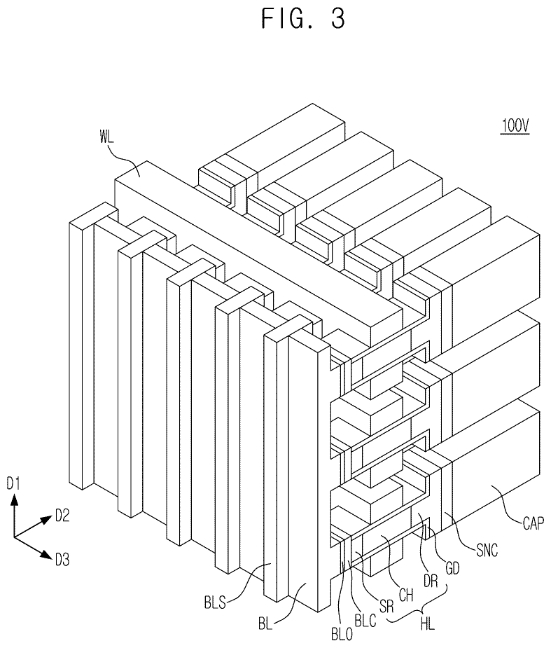

FIG. 3 is a schematic perspective view illustrating a semiconductor device 100V in accordance with an embodiment of the present disclosure. The semiconductor device 100V illustrated in FIG. 3 may include a structure in which the horizontal array illustrated in FIG. 2A is vertically stacked in a first direction D1. Detailed descriptions of overlapping components are provided above with reference to FIGS. 1A to 2C.

Referring to FIG. 3, the semiconductor device 100V may include a vertical stack of horizontal arrays HMCA. The semiconductor device 100V may include a horizontal arrangement of a plurality of first conductive lines BL and a vertical arrangement of a plurality of second conductive lines WL. A vertical arrangement of memory cells MC stacked in the first direction D1 may share one first conductive line BL. A horizontal arrangement of memory cells MC arranged in a third direction D3 may be coupled to different first conductive lines BL.

The horizontal arrangement of memory cells MC arranged in the third direction D3 may share one second conductive line WL. The vertical arrangement of memory cells MC stacked in the first direction D1 may be coupled to different second conductive lines WL.

Each of supporters BLS may be disposed between the first conductive lines BL adjacent to each other. The first conductive lines BL may be supported by the supporters BLS. The supporters BLS may vertically extend in the first direction. The supporters BLS may each include a dielectric material.

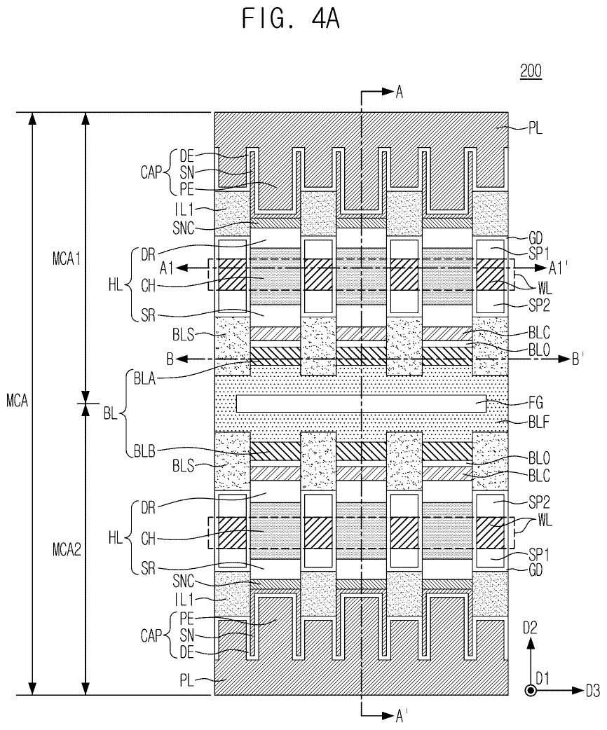

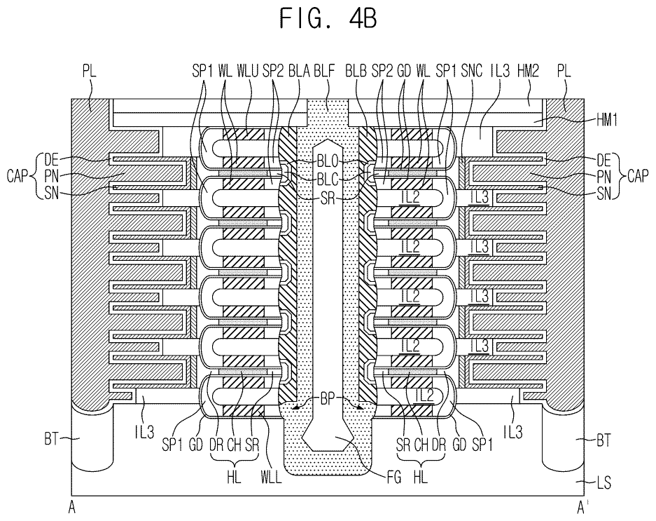

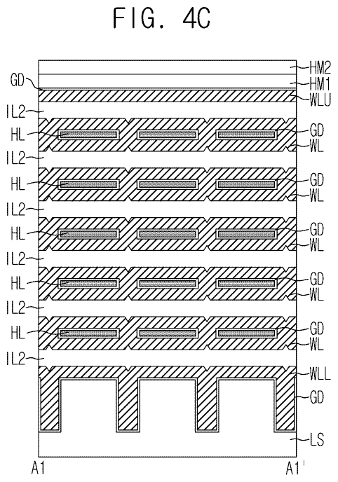

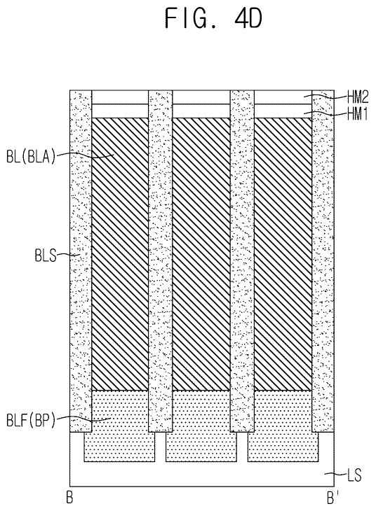

FIG. 4A is a schematic plan view illustrating a semiconductor device 200 in accordance with an embodiment of the present disclosure. FIG. 4B is a schematic cross-sectional view of the semiconductor device 200 taken along line A-A′ illustrated in FIG. 4A. FIG. 4C is a schematic cross-sectional view of the semiconductor device 200 taken along line A1-A1′ illustrated in FIG. 4A. FIG. 4D is a schematic cross-sectional view of the semiconductor device 200 taken along line B-B′ illustrated in FIG. 4A. Detailed descriptions of overlapping components are provided above with reference to FIGS. 1A to 3.

Referring to FIGS. 4A to 4D, the semiconductor device 200 may include a memory cell array MCA. The memory cell array MCA may include a three-dimensional array of memory cells MC. The memory cell array MCA may be formed over a lower structure LS.

The lower structure LS may be a material appropriate for semiconductor processing. The lower structure LS may include a semiconductor substrate, a conductive material, a dielectric material, a semiconductive material, or a combination thereof. The lower structure LS may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The lower structure LS may also include another semiconductor material such as germanium. The lower structure LS may also include a III-V group semiconductor substrate, for example, a compound semiconductor substrate such as GaAs.

Each of the memory cells MC may include a first conductive line BL, a switching element TR, and a data storage element CAP. The switching element TR may include a second conductive line WL, a nano sheet dielectric layer GD, and a nano sheet HL. The nano sheet HL may include a first doped region SR, a channel CH, and a second doped region DR.

The memory cell array MCA may include a column array of the memory cells MC and a row array of the memory cells MC. The column array may include a plurality of memory cells MC that are vertically stacked in a first direction D1. The memory cells MC of the column array may share the first conductive line BL. The row array may include a plurality of memory cells MC horizontally disposed in a third direction D3. The memory cells MC of the row array may share the second conductive line WL. The first direction D1 may be a vertical direction, and the third direction D3 may be a horizontal direction.

The memory cell array MCA may include a first sub-cell array MCA1 and a second sub-cell array MCA2. The first sub-cell array MCA1 and the second sub-cell array MCA2 may each include a three-dimensional array of the memory cells MC. The first sub-cell array MCA1 and the second sub-cell array MCA2 may share the first conductive line BL. The first conductive line BL may include a first vertical conductive line BLA and a second vertical conductive line BLB. A bottom portion of the first vertical conductive line BLA and a bottom portion of the second vertical conductive line BLB may be merged with each other. The first conductive line BL may have a U shape formed by merging the first vertical conductive line BLA and the second vertical conductive line BLB. The memory cells MC of the first sub-cell array MCA1 may share the first vertical conductive line BLA, and the memory cells MC of the second sub-cell array MCA2 may share the second vertical conductive line BLB. In this way, the neighboring first and second sub-cell arrays MCA1 and MCA2 may have a mirror-type structure of sharing the first conductive line BL. From the perspective of a top view, the first and second vertical conductive lines BLA and BLB may each have a rectangular shape.

Each of the memory cells MC of the first sub-cell array MCA1 may include the first vertical conductive line BLA, the switching element TR, and the data storage element CAP. The switching element TR may include the second conductive line WL and the nano sheet HL. Each of the memory cells MC of the second sub-cell array MCA2 may include the second vertical conductive line BLB, the switching element TR, and the data storage element CAP. The switching element TR may include the second conductive line WL, the nano sheet dielectric layer GD, and the nano sheet HL. The switching elements TR of the memory cells MC may be nano sheet transistors.

The first conductive line BL may vertically extend in the first direction D1. The nano sheet HL may extend in a second direction D2. The second conductive line WL may horizontally extend in the third direction D3.

A first inter-cell dielectric layer IL1 may be disposed between the data storage elements CAP disposed adjacent to each other in the third direction D3. A second inter-cell dielectric layer IL2 may be disposed between the second conductive lines WL vertically stacked in the first direction D1. A third inter-cell dielectric layer IL3 may be disposed between first electrodes SN of the data storage elements CAP vertically stacked in the first direction D1. The first to third inter-cell dielectric layers IL1, IL2 and IL3 may each include silicon oxide, silicon carbon oxide (SiCO), silicon nitride, or a combination thereof. The first inter-cell dielectric layer IL1 may be referred to as a “device isolation layer”.

Each of the memory cells MC may further include a first contact node BLC and a second contact node SNC. The first contact node BLC may be disposed between the first conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and a first doped region SR may include an impurity diffused from the first contact node BLC. The second contact node SNC may be disposed between the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped polysilicon, and a second doped region DR may include an impurity diffused from the second contact node SNC. A height of the first contact node BLC in the first direction D1 may be less than a height of the second contact node SNC in the first direction D1. The height of the first contact node BLC in the first direction D1 may be greater than a height of the channel CH in the first direction D1. The first and second contact nodes BLC and SNC may each include polysilicon doped with an N-type impurity, for example, phosphorus-doped polysilicon or arsenic-doped polysilicon.

The memory cell MC may further include an ohmic contact layer BLO between the first contact node BLC and the first conductive line BL. The ohmic contact layer BLO may include metal silicide, such as titanium silicide or molybdenum silicide.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The first and second spacers SP1 and SP2 may each include a dielectric material. The first and second spacers SP1 and SP2 may each include silicon oxide, silicon nitride, or a combination thereof. The second spacer SP2 may include a first liner L1 and a second liner L2, as described above with reference to FIG. 1B. As described above with reference to FIG. 2B, the first spacer SP1 may extend in the third direction D3 while surrounding portions of the nano sheets HL disposed at the same horizontal level. As described above with reference to FIG. 2C, the second spacer SP2 may extend in the third direction D3 while surrounding portions of the nano sheets HL disposed at the same horizontal level.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may include a dummy second conductive line WLU disposed at a level higher than an uppermost second conductive line WL and a dummy second conductive line WLL disposed at a level lower than a lowermost second conductive line WL. The dummy second conductive lines WLU and WLL may each have a linear shape extending horizontally.

The memory cell array MCA may include a stack of a plurality of hard mask layers HM1 and HM2 disposed at a level higher than the uppermost second conductive line WL.

The memory cell array MCA may include a plurality of bottom protection layers BT. The bottom protection layers BT may prevent the data storage element CAP and the lower structure LS from coming into electrical contact with each other. The bottom protection layers BT may each include a dielectric material.

An array isolation layer BLF may be disposed between the first vertical conductive line BLA and the second vertical conductive line BLB of the first conductive line BL. The array isolation layer BLF may include a dielectric material. The array isolation layer BLF may include an air gap FG and bridge preventing portions BP. The air gap FG may reduce parasitic capacitance between the first vertical conductive line BLA and the second vertical conductive line BLB that are adjacent to each other. The bridge preventing portions BP of the array isolation layer BLF may prevent bridging between bottom portions of the first and second vertical conductive lines BLA and BLB and the lower structure LS. Although the bottom portions of the first and second vertical conductive lines BLA and BLB are close to the lower structure LS, the bridge preventing portions BP of the array isolation layer BLF may prevent bridging between the bottom portions of the first and second vertical conductive lines BLA and BLB and the lower structure LS. Because heights of the bridge preventing portions BP are low, the bottom portions of the first and second vertical conductive lines BLA and BLB may be formed close to the lower structure LS.

In an embodiment, because the bottom portions of the first and second vertical conductive lines BLA and BLB are formed close to the lower structure LS, dummy memory cells may not be generated. Because the dummy memory cells are not present, it is possible to increase memory cell density.

Referring back to FIGS. 4A and 4D, the first and second vertical conductive lines BLA and BLB may be supported by supporters BLS. The supporters BLS may vertically extend in the first direction D1. The supporters BLS may each include a dielectric material. The first and second vertical conductive lines BLA and BLB may be formed to be self-aligned with the supporters BLS. The first vertical conductive lines BLA adjacent to each other in the third direction D3 may be isolated from each other by the supporters BLS. The second vertical conductive lines BLB adjacent to each other in the third direction D3 may be isolated from each other by the supporters BLS. The first vertical conductive lines BLA and the second vertical conductive lines BLB adjacent to each other in the second direction D2 may be isolated from each other by the array isolation layer BLF.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

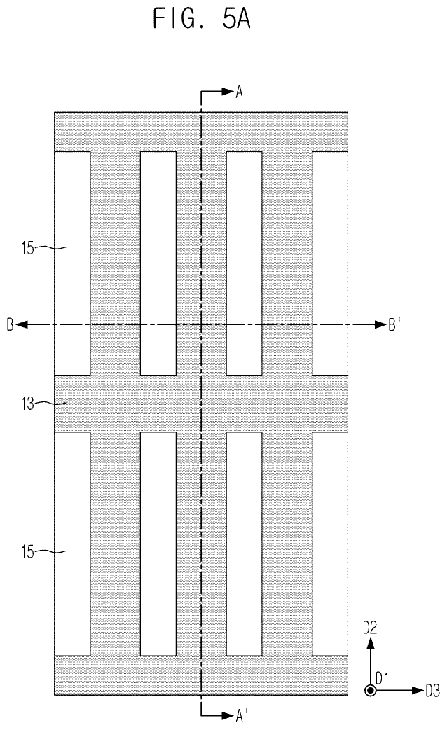

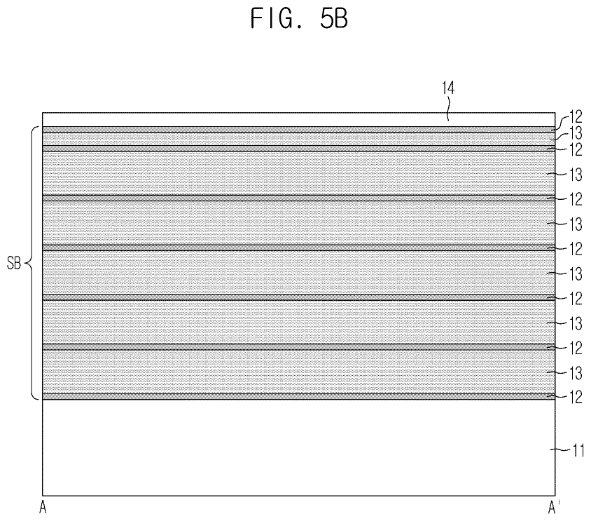

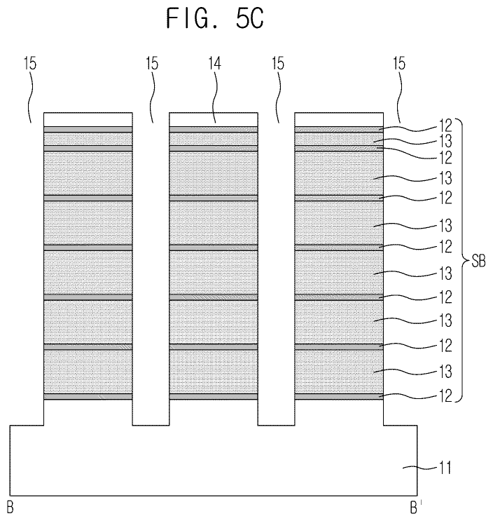

FIGS. 5A to 28B illustrate various views of a semiconductor device formed utilizing a method for fabricating the semiconductor device in accordance with an embodiment of the present disclosure.

FIG. 5A is a plan view illustrating a structure at a second mold layer level to describe a method for forming a mold stack SB. FIG. 5B is a cross-sectional view of the structure taken along line A-A′ illustrated in FIG. 5A. FIG. 5C is a cross-sectional view of the structure taken along line B-B′ illustrated in FIG. 5A.

Referring to FIGS. 5A to 5C, the mold stack SB may be formed on a substrate 11. The substrate 11 may be a material appropriate for semiconductor processing. The substrate 11 may include a semiconductor substrate, a conductive material, a dielectric material, a semiconductive material, or a combination thereof. The substrate 11 may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The substrate 11 may also include another semiconductor material such as germanium. The substrate 11 may also include a III-V group semiconductor substrate, for example, a compound semiconductor substrate such as GaAs. The mold stack SB may include an alternating stack of first mold layers 12 and second mold layers 13.

To form the mold stack SB, the first mold layers 12 may be alternately stacked with the second mold layers 13, and the first mold layers 12 and the second mold layers 13 may be epitaxially grown multiple times.

The first mold layers 12 and the second mold layers 13 may be different semiconductive materials. The first mold layers 12 may each include silicon germanium or monocrystalline silicon germanium. The second mold layers 13 may each include monocrystalline silicon. The first mold layers 12 and the second mold layers 13 may be formed by an epitaxial growth process. A lowermost first mold layer 12 may serve as a seed layer during the epitaxial growth process. Each of the first mold layers 12 may be thinner than each of the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and a thickness ratio of the second mold layers 13 in the mold stack SB may be variously modified. For example, the thickness of the first mold layers 12 may be 5 to 20 nm, and the thickness of the second mold layers 13 may be 50 to 80 nm. A quantity of the first mold layers 12 and a quantity of the second mold layers 13 in the mold stack SB may be variously modified. In some embodiments, a triple stack including the first mold layer 12, the second mold layer 13 and the first mold layer 12 may be defined at lowermost and/or uppermost portions of the mold stack SB. In an embodiment, the triple stack including the first mold layer 12, the second mold layer 13 and the first mold layer 12 may be formed at the uppermost portion of the mold stack SB. The second mold layer 13 of the triple stack may have a thickness less than the other second mold layers 13 of the mold stack SB.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

Referring back to FIGS. 5A and 5C, portions of the mold stack SB may be etched using the first hard mask layer 14 as a barrier, and a plurality of sacrificial isolation openings 15 may be formed. The sacrificial isolation openings 15 may be initial openings for cell isolation. From the perspective of a top view, cross-sections of the sacrificial isolation openings 15 may each have a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. A bottom surface of each of the sacrificial isolation openings 15 may extend inside of the substrate 11.

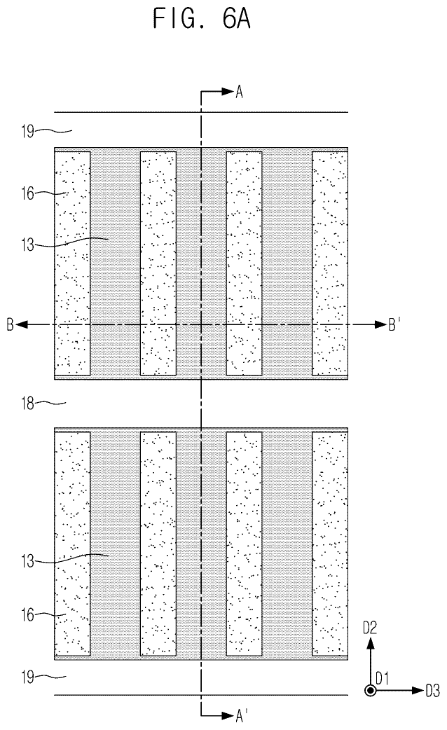

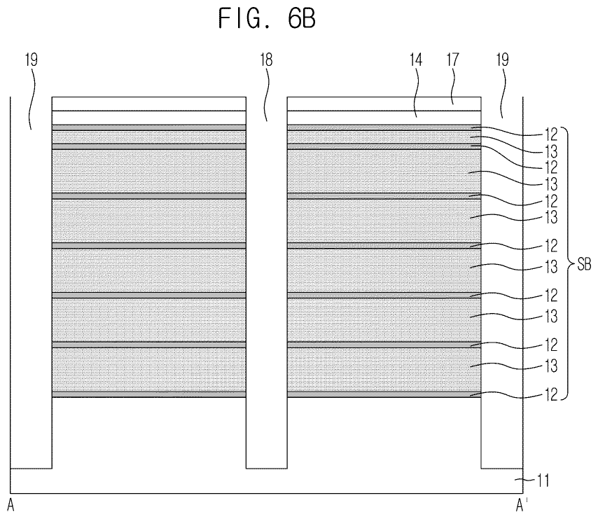

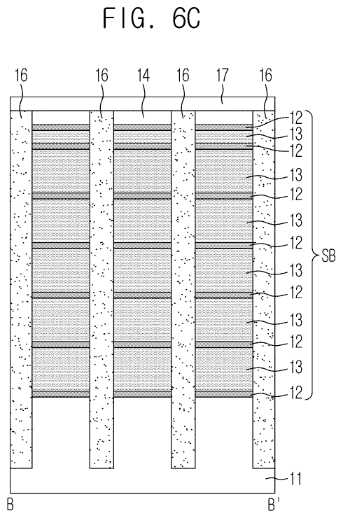

FIG. 6A is a plan view illustrating the structure at the second mold layer level to describe a method for forming sacrificial linear openings 18 and 19. FIG. 6B is a cross-sectional view of the structure taken along line A-A′ illustrated in FIG. 6A. FIG. 6C is a cross-sectional view of the structure taken along line B-B′ illustrated in FIG. 6A.

Referring to FIGS. 6A to 6C, sacrificial isolation layers 16 may be formed to fill the sacrificial isolation openings 15. The sacrificial isolation layers 16 may include the same material. The sacrificial isolation layers 16 may be each formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the mold stack SB to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. Each of the sacrificial isolation layers 16 may include a stack of a first sacrificial liner layer and a first sacrificial gap-fill layer. The first sacrificial liner layer may be silicon nitride, and the first sacrificial gap-fill layer may be silicon oxide. The sacrificial isolation layers 16 may penetrate the mold stack SB in the first direction D1.

Subsequently, a second hard mask layer 17 may be formed on the mold stack SB and the sacrificial isolation layers 16. The second hard mask layer 17 may include silicon nitride. The second hard mask layer 17 may be formed by etching a second hard mask material using a mask layer such as photoresist. The second hard mask layer 17 may have a plurality of line-shaped openings defined therein.

Portions of the mold stack SB may be etched using the second hard mask layer 17 as an etch barrier. Accordingly, a plurality of sacrificial linear openings 18 and 19 may be formed between the sacrificial isolation layers 16. The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a circular shape or an oval shape. The first and second sacrificial linear openings 18 and 19 may each have a width in the second direction D2 which is less than a width in the third direction D3. The first and second sacrificial linear openings 18 and 19 may be referred to as “sacrificial linear trenches”. The first sacrificial linear opening 18 and the second sacrificial linear opening 19 may have different horizontal lengths in the third direction D3. The sacrificial isolation layers 16 may not contact the first and second sacrificial linear openings 18 and 19.

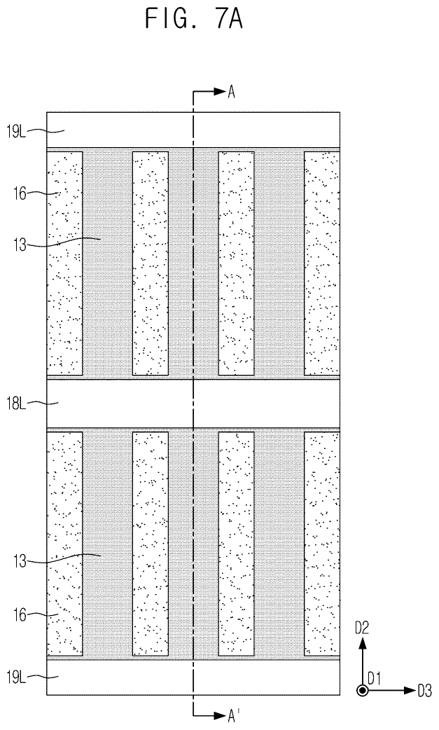

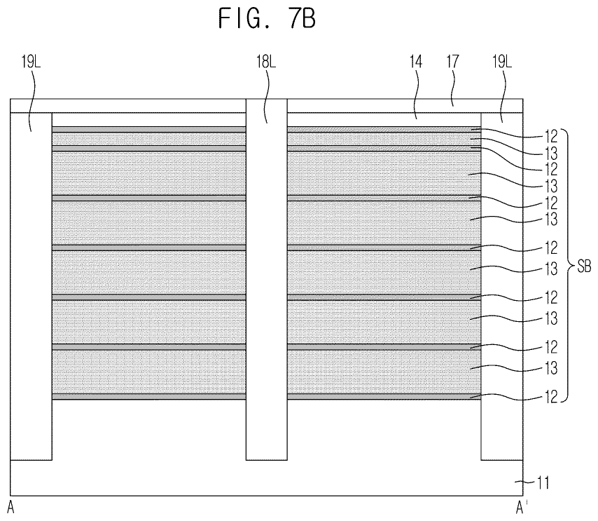

FIG. 7A is a plan view illustrating the structure at the second mold layer level to describe a method for forming linear sacrificial layers 18L and 19L, and FIG. 7B is a cross-sectional view of the structure taken along line A-A′ illustrated in FIG. 7A.

Referring to FIGS. 7A and 7B, the linear sacrificial layers 18L and 19L may be formed to fill the first and second sacrificial linear openings 18 and 19. The linear sacrificial layers may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may be each formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

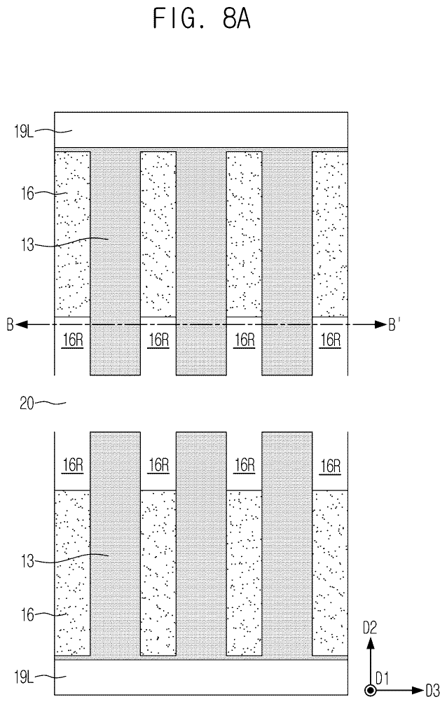

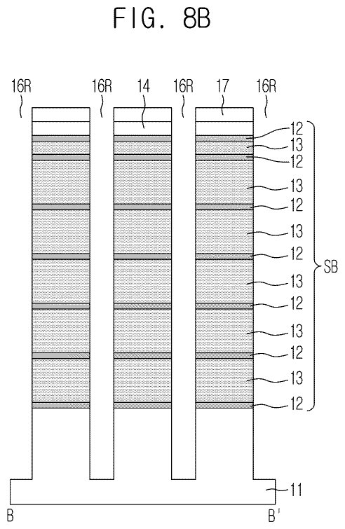

FIG. 8A is a plan view illustrating the structure at a mold layer level to describe a method for forming supporter holes 16R, and FIG. 8B is a cross-sectional view of the structure taken along line B-B′ illustrated in FIG. 8A.

Referring to FIGS. 8A and 8B, among the first linear sacrificial layer 18L and the second linear sacrificial layer 19L, the first linear sacrificial layer 18L may be selectively removed. Accordingly, a first linear opening 20 may be formed. From the perspective of a top view, the first linear openings 20 may be disposed horizontally spaced apart from the second linear sacrificial layer 19L in the second direction D2.

One edge of each of the sacrificial isolation layers 16 may be exposed by the first linear opening 20.

Subsequently, the first and second mold layers 12 and 13 of the mold stack SB may be partially recessed in the second direction D2 through the first linear opening 20.

Subsequently, portions of the sacrificial isolation layers 16 may be recessed in the second direction D2 through the first linear opening 20. Accordingly, the supporter holes 16R may be formed.

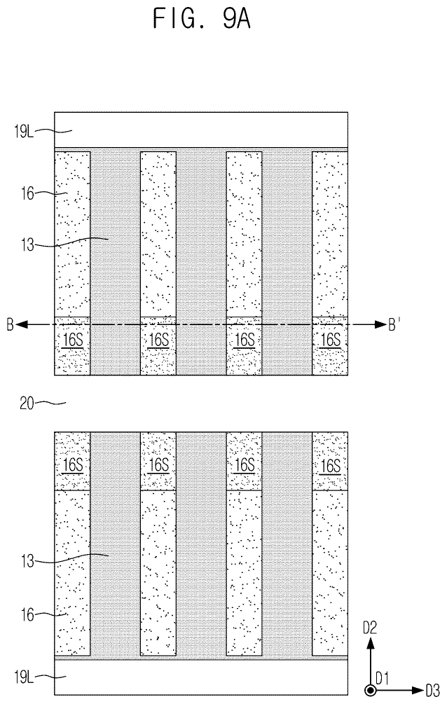

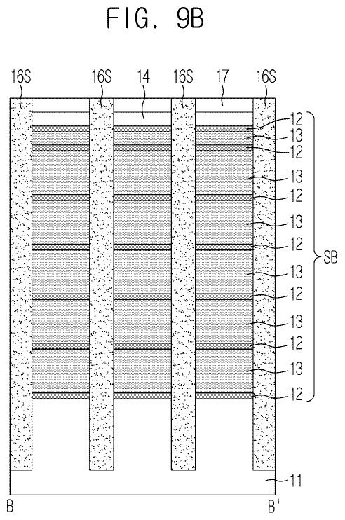

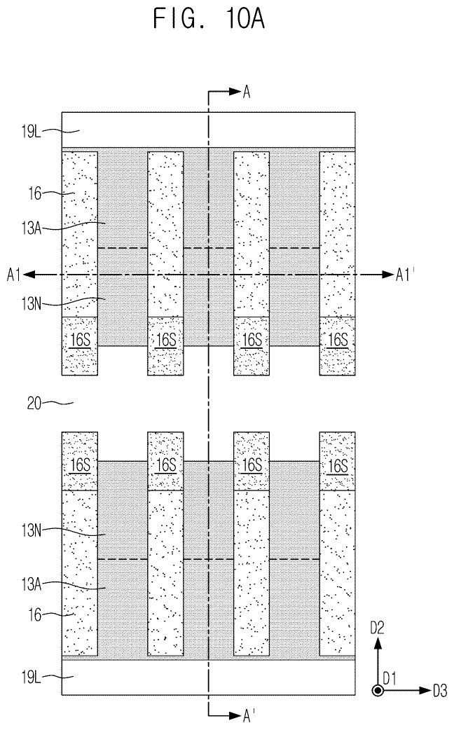

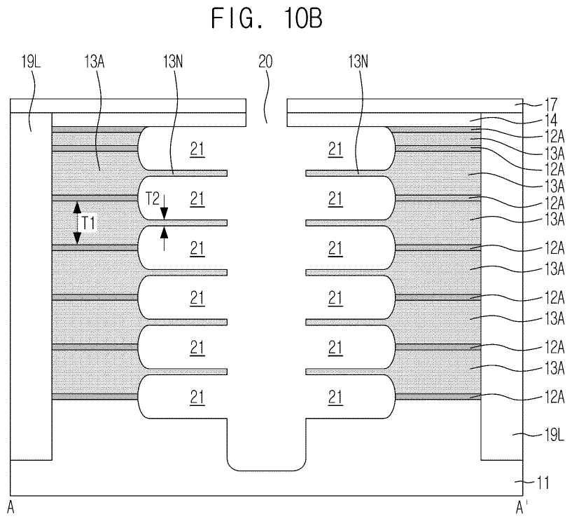

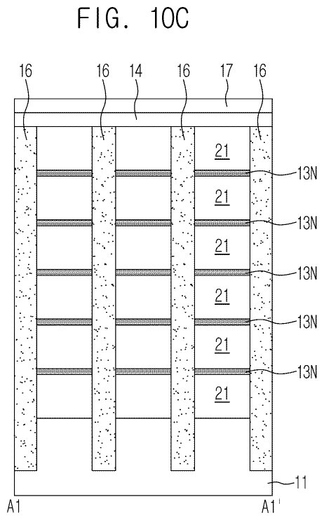

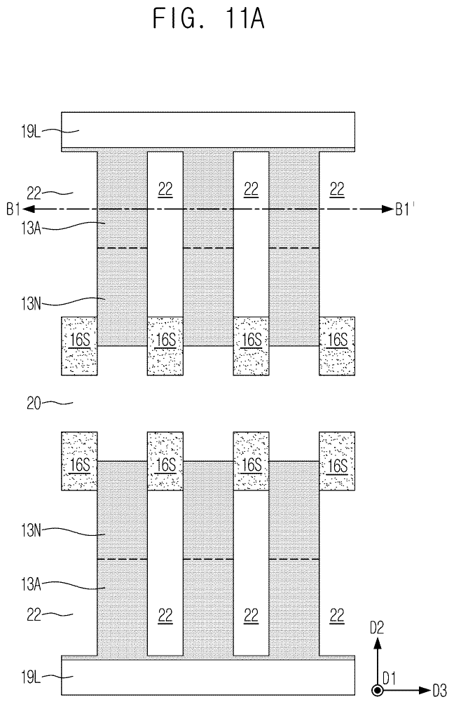

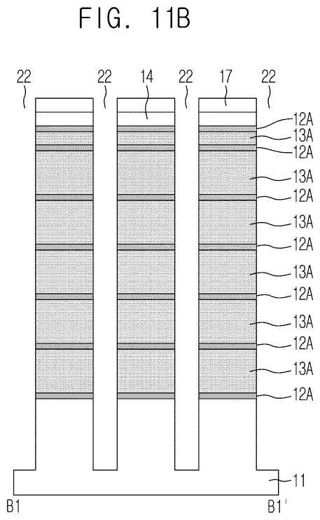

FIG. 9A is a plan view illustrating the structure at the second mold layer level to describe a method for forming supporters 16S, and FIG. 9B is a cross-sectional view of the structure taken along line B-B′ illustrated in FIG. 9A.

Referring to FIGS. 9A and 9B, the supporters 16S may be formed to fill the supporter holes 16R. The supporters 16S may each include a dielectric material. In an embodiment, the supporters 16S may each include silicon nitride. The supporters 16S may have an etching selectivity with respect to the sacrificial isolation layers 16.

The supporters 16S may correspond to the supporters BLS illustrated in FIGS. 4A to 4D.

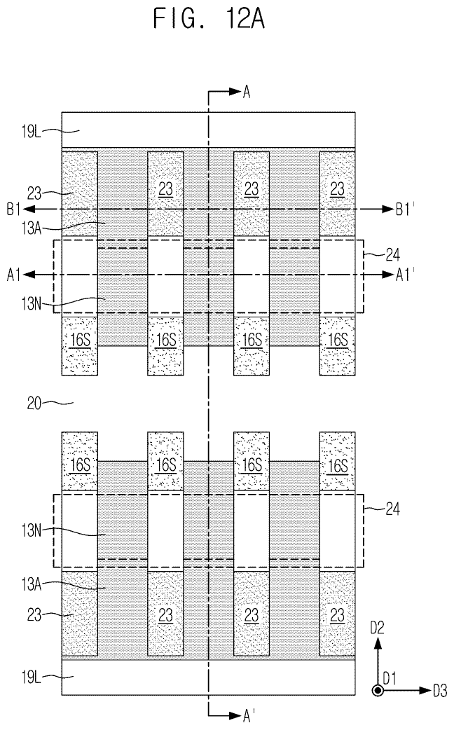

FIG. 10A is a plan view illustrating the structure at the second mold layer level to describe recessing of the first and second mold layers 12 and 13. FIG. 10B is a cross-sectional view of the structure taken along line A-A′ illustrated in FIG. 10A. FIG. 10C is a cross-sectional view of the structure taken along line A-A1′ illustrated in FIG. 10A.

Referring to FIGS. 10A to 10C, the first mold layers 12 may be selectively recessed through the first linear opening 20.

A difference in etch selectivity between the first mold layers 12 and the second mold layers 13 may be used to selectively recess the first mold layers 12. The first mold layers 12 may be removed using a wet etch process or a dry etch process. For example, when the first mold layers 12 include silicon germanium layers, and the second mold layers 13 include monocrystalline silicon layers, the silicon germanium layers may be etched using an etchant or etch gas having a selectivity with respect to the monocrystalline silicon layers. The first mold layers each having an original thickness may remain as indicated by reference numeral “12A”.

Subsequently, a portion (a first portion) of each of the second mold layers 13 may be recessed to form a narrow sheet 13N. The wet etch process or dry etch process may be used to recess the second mold layers 13. An original body portion 13A and the narrow sheet 13N may be formed by the partial recessing of each of the second mold layers 13. The original body portion 13A may maintain an original thickness T1, and the narrow sheet 13N may have a thickness T2 less than the original thickness T1. A horizontal length of the original body portion 13A in the second direction D2 may be equal to or different from a horizontal length of the narrow sheet 13N in the second direction D2. A combination of the original body portion 13A and the narrow sheet 13N may be referred to as a “preliminary active layer”. The narrow sheet 13N may be referred to as a “flat plate-shaped sheet” or a “protruding narrow sheet”.

A recess process for forming the narrow sheet 13N may be referred to as a “thinning process” or “trimming process” of the second mold layer 13. To form the narrow sheet 13N, an upper surface, lower surface and side surface of the second mold layer 13 may be recessed. The narrow sheet 13N may be referred to as a “thin-body active layer”. The narrow sheet 13N may include a monocrystalline silicon layer. The recess process for forming the narrow sheet 13N may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:20. Using the HSC1, the second mold layers 13 may be selectively etched.

The narrow sheets 13N may be formed by the partial recess process for the second mold layers 13 as described above. Each of inter-nano sheet recesses 21 may be formed between the narrow sheets 13N that are vertically disposed. Upper and lower surfaces of each of the narrow sheets 13N may each include a flat surface. A boundary portion between the original body portion 13A and the narrow sheet 13N may be vertical or have a curvature. Each of the first mold layers 12A may be disposed between the original body portions 13A that are vertically stacked.

Each of the supporters 16A may be disposed between the narrow sheets 13N adjacent to each other in the third direction D3.

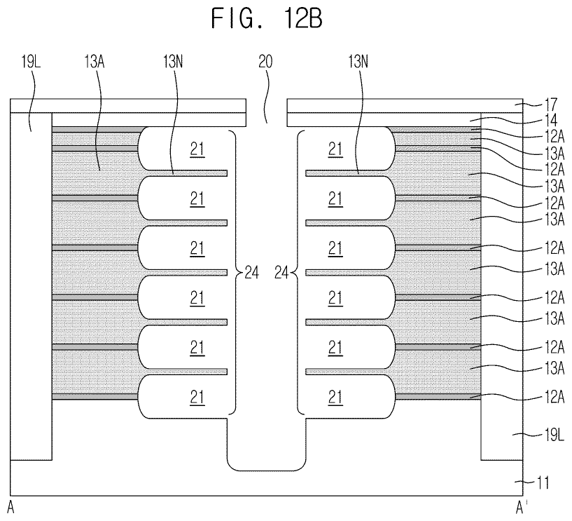

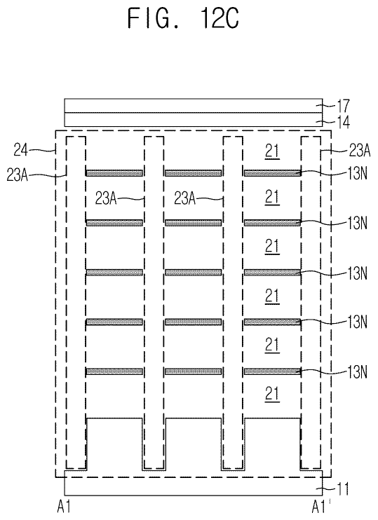

FIG. 11A is a plan view illustrating the structure at a narrow sheet level to describe a method for forming sacrificial isolation layer-level openings 22, and FIG. 11B is a cross-sectional view of the structure taken along line B1-B1′ illustrated in FIG. 11A.

Referring to FIGS. 11A and 11B, the sacrificial isolation layers 16 may be selectively stripped through the inter-nano sheet recesses 21. Accordingly, each of the sacrificial isolation layer-level openings 22 may be formed between the original body portions 13A in the third direction D3. Each of the supporters 16S may be disposed between the narrow sheets 13N adjacent to each other in the third direction D3. The supporters 16S may not be removed while the sacrificial isolation layers 16 are removed.

Side surfaces of the first mold layers 12A, side surfaces of the original body portions 13A and side surfaces of the narrow sheets 13N may be exposed in the third direction D3 by the sacrificial isolation layer-level openings 22.

While the sacrificial isolation layers 16 are removed, the supporters 16S may prevent the narrow sheets 13N from collapsing.

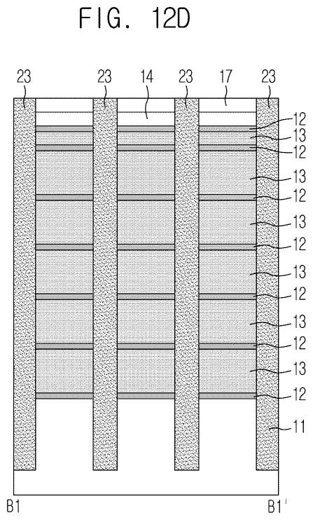

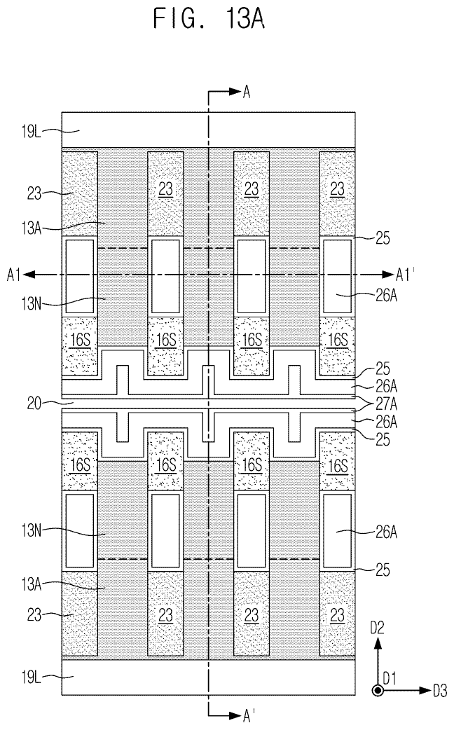

FIG. 12A is a plan view illustrating the structure at the narrow sheet level to describe a method for forming first inter-cell dielectric layers 23. FIG. 12B is a cross-sectional view of the structure taken along line A-A′ illustrated in FIG. 12A. FIG. 12C is a cross-sectional view of the structure taken along line A1-A1′ illustrated in FIG. 12A. FIG. 12D is a cross-sectional view of the structure taken along line B1-B1′ illustrated in FIG. 12A.

Referring to FIGS. 12A to 12D, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13N. The other portions of the sacrificial isolation layer-level openings 22, i.e., non-gap-filled portions 23A, may expose the side surfaces of the narrow sheets 13N. The non-gap-filled portions 23A may be defined between the narrow sheets 13N in the third direction D3.

After the first inter-cell dielectric layers 23 are formed, a nano sheet all-open recess 24 that opens all of the narrow sheets 13N may be formed. The nano sheet all-open recess 24 may refer to a combination of the inter-nano sheet recesses 21 and the non-gap-filled portions 23A of the first inter-cell dielectric layers 23. The nano sheet all-open recess 24 may expose the plurality of narrow sheets 13N in the third direction D3.

The nano sheet all-open recess 24 may expose all of the first portions of the narrow sheets 13N, and one edge of each of the narrow sheets 13N, i.e., second portions, may be supported by the supporters 16S. From the perspective of a top view, the nano sheet all-open recess 24 may be defined between the first inter-cell dielectric layers 23 and the supporters 16S.

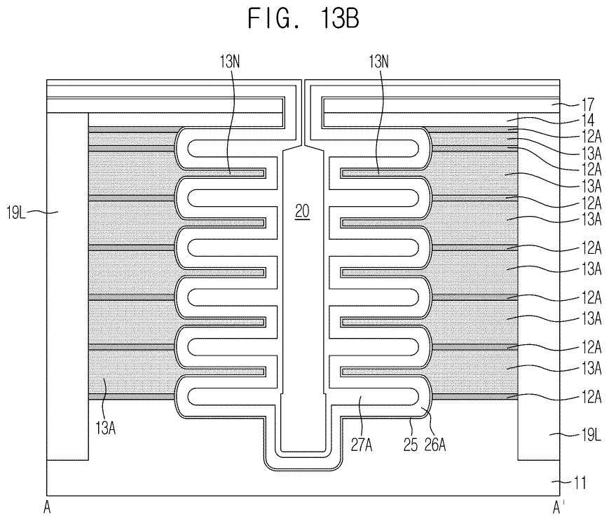

FIG. 13A is a plan view illustrating the structure at the narrow sheet level to describe a method for forming a first spacer layer 26A. FIG. 13B is a cross-sectional view of the structure taken along line A-A′ illustrated in FIG. 13A. FIG. 13C is a cross-sectional view of the structure taken along line A1-A1′ illustrated in FIG. 13A.

Referring to FIGS. 13A to 13C, a nano sheet dielectric layer 25 may be formed on exposed portions of the narrow sheets 13N. The nano sheet dielectric layer 25 may be referred to as a “gate dielectric layer”.

The nano sheet dielectric layer 25 may be formed by oxidizing the surfaces of the narrow sheets 13N. In some embodiments, the nano sheet dielectric layer 25 may be formed by deposition and oxidation processes of silicon oxide. The nano sheet dielectric layer 25 may include silicon oxide, silicon nitride, metal oxide, metal oxynitride, metal silicate, a high-k material, a ferroelectric material, an anti-ferroelectric material, or a combination thereof. The nano sheet dielectric layer 25 may include SiO₂, Si₃N₄, HfO₂, Al₂O₃, ZrO₂, AlON, HfON, HfSiO, HfSiON, or a combination thereof. The nano sheet dielectric layer 25 may be formed on all the surfaces of the narrow sheets 13N.

The first spacer layer 26A may be formed on the nano sheet dielectric layer 25. The first spacer layer 26A may include silicon nitride. The first spacer layer 26A may surround and cover the narrow sheets 13N on the nano sheet dielectric layer 25. The first spacer layer 26A may be thicker than the nano sheet dielectric layer 25. From the perspective of a top view, the first spacer layer 26A may fill a space between the first inter-cell dielectric layers 23 and the supporters 16S, that is, the nano sheet-all open recess 24.

Second inter-cell dielectric layers 27A may be formed on the first spacer layer 26A. The second inter-cell dielectric layers 27A may each include silicon oxide. The first spacer layer 26A and the second inter-cell dielectric layers 27A may partially fill the first linear opening 20. A stack of the first spacer layer 26A and the second inter-cell dielectric layers 27A may fill the nano sheet-all open recess 24.

The nano sheet dielectric layer 25 and the first spacer layer 26A may also be formed on the surface of the substrate 11.

As described above, the first spacer layer 26A may be disposed between the narrow sheets 13N in the third direction D3.

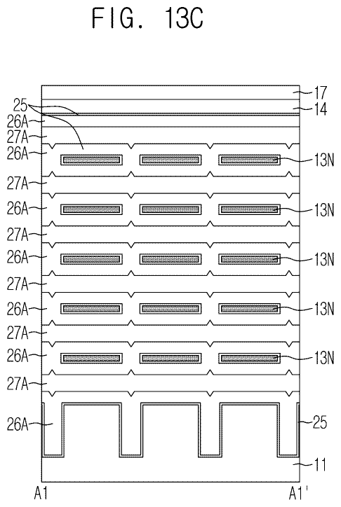

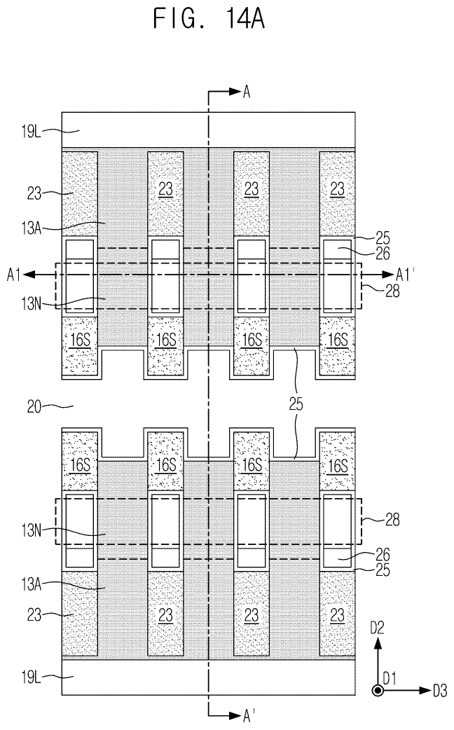

FIG. 14A is a plan view illustrating the structure at the narrow sheet level to describe a method for forming first spacers 26. FIG. 14B is a cross-sectional view of the structure taken along line A-A′ illustrated in FIG. 14A. FIG. 14C is a cross-sectional view of the structure taken along line A1-A1′ illustrated in FIG. 14A.

Referring to FIGS. 14A to 14C, the second inter-cell dielectric layers 27A may be cut through the first linear opening 20. Subsequently, the first spacer layer 26A may be selectively recessed. The remaining first spacer layers may become the first spacers 26, and the second inter-cell dielectric layers may remain as indicated by reference numeral “27”. From the perspective of a top view, the first spacers 26 may be disposed between the first inter-cell dielectric layers 23 and the supporters 16S.

As the first spacers 26 are formed, linear surrounding recesses 28 surrounding the narrow sheets 13N may be formed on the nano sheet dielectric layer 25. Each of the second inter-cell dielectric layers 27 may be disposed between the linear surrounding recesses 28 that are vertically disposed. Dummy recesses 28U and 28L may be formed at higher and lower levels than the linear surrounding recesses 28. From the perspective of a top view, the linear surrounding recesses 28 may be defined between the first spacers 26 and the supporters 16S.

The first spacers 26 may correspond to the first spacer SP1 illustrated in FIGS. 4a to 4c.

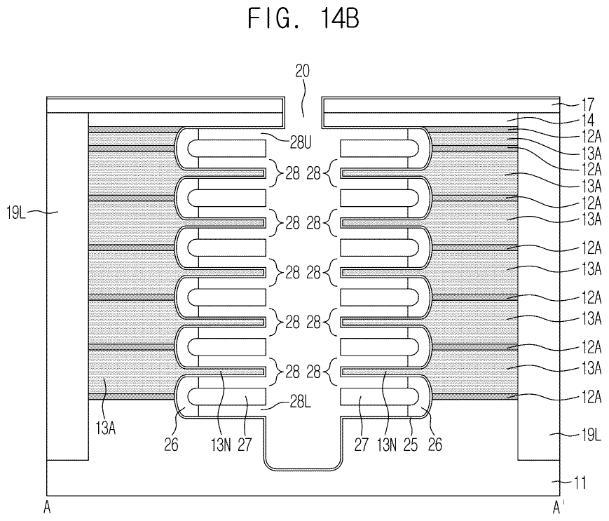

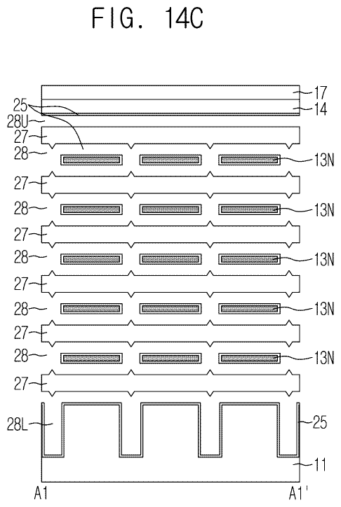

FIG. 15A is a plan view illustrating the structure at the narrow sheet level to describe a method for forming horizontal conductive lines 29. FIG. 15B is a cross-sectional view of the structure taken along line A-A′ illustrated in FIG. 15A. FIG. 15C is a cross-sectional view of the structure taken along line A1-A1′ illustrated in FIG. 15A.

Referring to FIGS. 15A to 15C, the horizontal conductive lines 29 may be formed to fill the linear surrounding recesses 28. The horizontal conductive lines 29 may horizontally extend in the third direction D3. The horizontal conductive lines 29 may correspond to the second conductive lines WL illustrated in FIGS. 4A to 4C.

Forming the horizontal conductive lines 29 may include depositing a conductive material filling the linear surrounding recesses 28 on the nano sheet dielectric layer 25 and performing a horizontal etch-back process on the conductive material. Each of the horizontal conductive lines 29 may simultaneously surround the narrow sheets 13N at the same level. The horizontal conductive lines 29 may each include a metal-based material, a semiconductive material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or less, and the P-type work function material may have a high work function of approximately 4.5 eV or greater. Each of the second inter-cell dielectric layers 27 may be disposed between a plurality of horizontal conductive lines 29 in the first direction D1. The horizontal conductive lines 29 may surround the narrow sheets 13N at the same horizontal level in the third direction D3. The horizontal conductive lines 29 may be referred to as “gate-all-around (GAA) electrodes”. The narrow sheets 13N may be referred to as “nano sheet channels”, “nano wires” or “nano wire channels”.

A lower-level dummy horizontal electrode 29L may be formed on the surface of the substrate 11. An upper-level dummy horizontal electrode 29U may be formed over an uppermost horizontal conductive line 29. The dummy horizontal electrodes 29L and 29U may each have a non-surrounding shape.

The horizontal conductive lines 29 may include surrounding portions surrounding the narrow sheets 13N and gap-fill portions disposed between the narrow sheets 13N. From the perspective of a top view, the gap-fill portions of the horizontal conductive lines 29 may be disposed between the first spacers 26 and the supporters 16S.

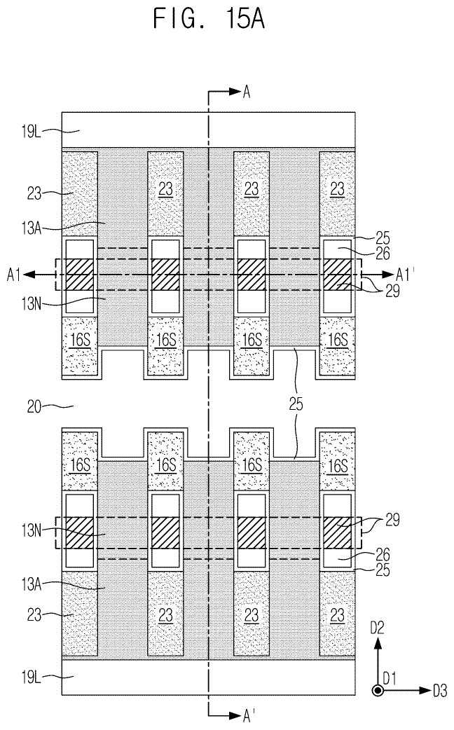

FIG. 16A is a plan view illustrating the structure at the narrow sheet level to describe a method for forming second spacers 30. FIG. 16B is a cross-sectional view of the structure taken along line A-A′ illustrated in FIG. 16A.

Referring to FIGS. 16A and 16B, each of the second spacers 30 may be formed on one side of each of the horizontal conductive lines 29. The second spacer 30 may include silicon oxide, silicon nitride, silicon carbon oxide, an embedded air gap, or a combination thereof. Deposition and etch-back processes of a spacer material may be performed to form the second spacer 30. The second spacer 30 may include a stack of a silicon oxide liner and a silicon nitride liner. The second spacer 30 may correspond to the second spacer SP2 illustrated in FIGS. 4A to 4C.

After the second spacers 30 are formed, a portion of the nano sheet dielectric layer 25 may be cut to expose one side of each of the narrow sheets 13N.

Each of the second spacers 30 may be disposed on one side of each of the horizontal conductive lines 29 and surround the narrow sheets 13N at the same horizontal level in the third direction D3.

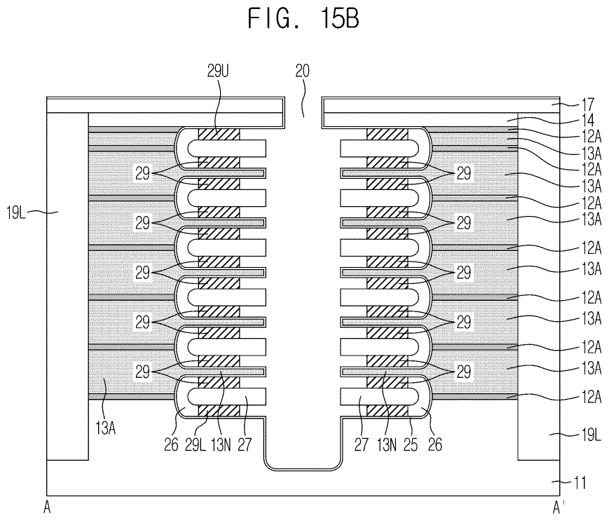

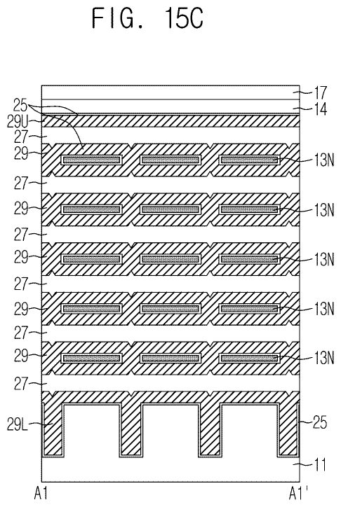

FIG. 17A is a plan view illustrating the structure at the narrow sheet level to describe a method for forming narrow sheet cuts 13R. FIG. 17B is a cross-sectional view of the structure taken along line A-A′ illustrated in FIG. 17A.

Referring to FIGS. 17A and 17B, one side surface E1 of the narrow sheets 13N may be cut. Accordingly, the narrow sheet cuts 13R may be formed to be horizontally recessed from the edges of the first spacer 26. While the narrow sheet cuts 13R are formed, the surface of the substrate 11 may be recessed, and then a substrate recessing 13R′ may be formed.

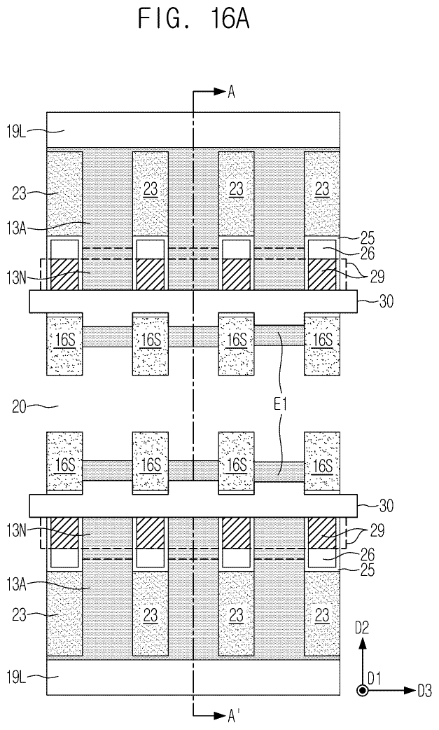

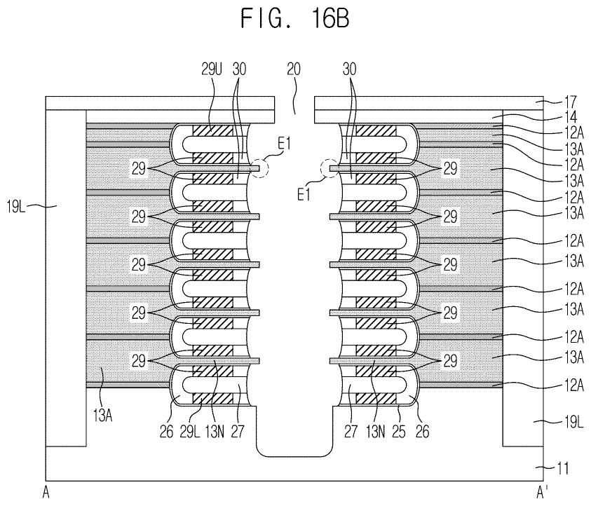

FIG. 18A is a plan view illustrating the structure at the narrow sheet level to describe a method for forming a sacrificial protection layer 32. FIG. 18B is a cross-sectional view of the structure taken along line A-A′ illustrated in FIG. 18A.

Referring to FIGS. 18A and 18B, sacrificial pocket layers 31 may be formed to fill the narrow sheet cuts 13R. The sacrificial pocket layers 31 may be formed by deposition and etch processes of silicon oxide. Portions of the second spacers 30 may be recessed while the sacrificial pocket layers 31 are formed.

Subsequently, the sacrificial protection layer 32 may be grown on a surface of the substrate recessing 13R′. The protection layer 32 may be selectively grown from the surface of the substrate recessing 13R′. The sacrificial protection layer 32 may include a silicon germanium layer. The sacrificial protection layer 32 may not be grown on the surface of the narrow sheets 13N due to the sacrificial pocket layers 31.

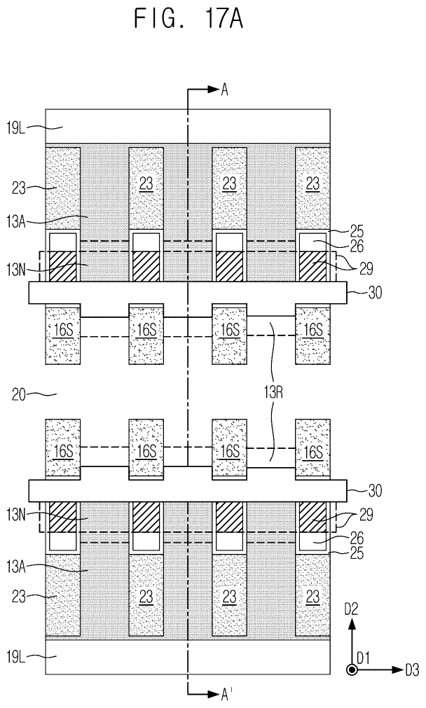

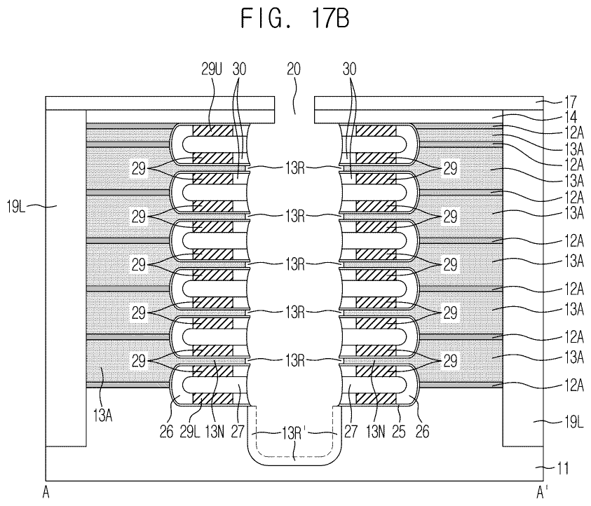

FIG. 19A is a plan view illustrating the structure at the narrow sheet level to describe a method for forming vertical openings VL. FIG. 19B is a cross-sectional view of the structure taken along line A-A′ illustrated in FIG. 19A.

Referring to FIGS. 19A and 19B, the sacrificial pocket layers 31 may be selectively removed. Accordingly, the vertical openings VL may be formed to expose edges E2 of the narrow sheets 13N. From the perspective of a top view, the vertical openings VL may be formed to be self-aligned by the supporters 16S, thereby defining the vertical openings VL between the supporters 16S. The sacrificial protection layer 32 may remain below the vertical openings VL.

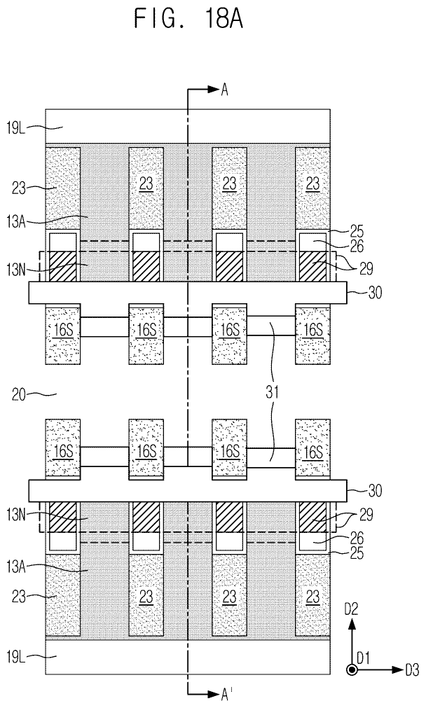

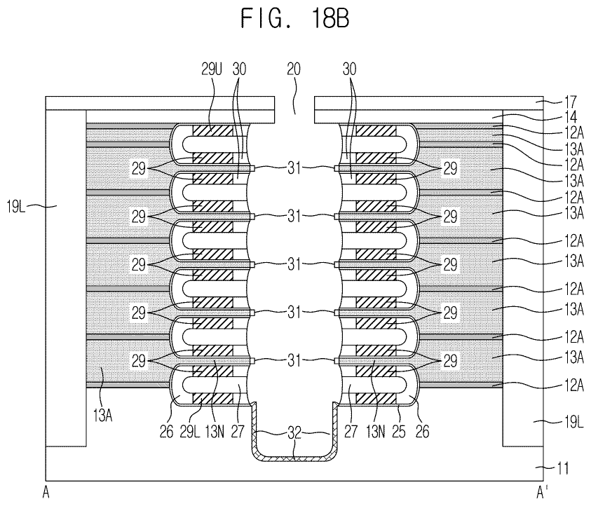

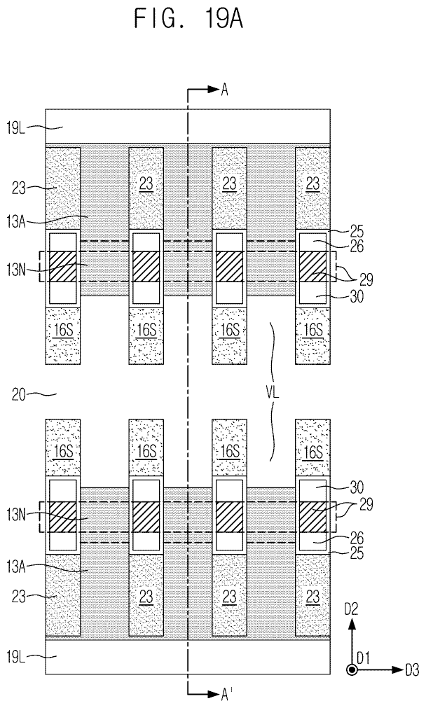

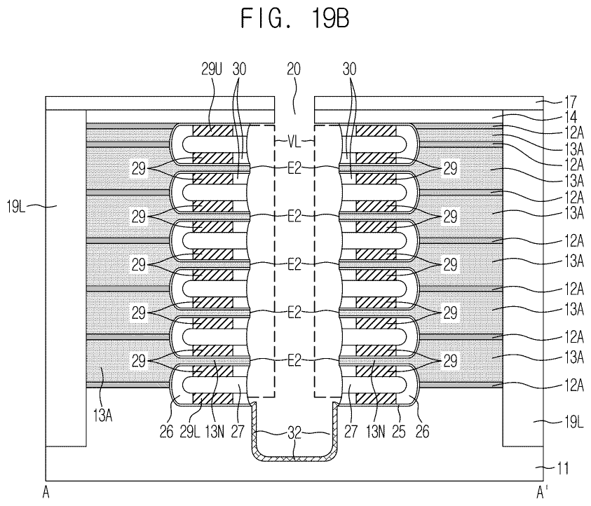

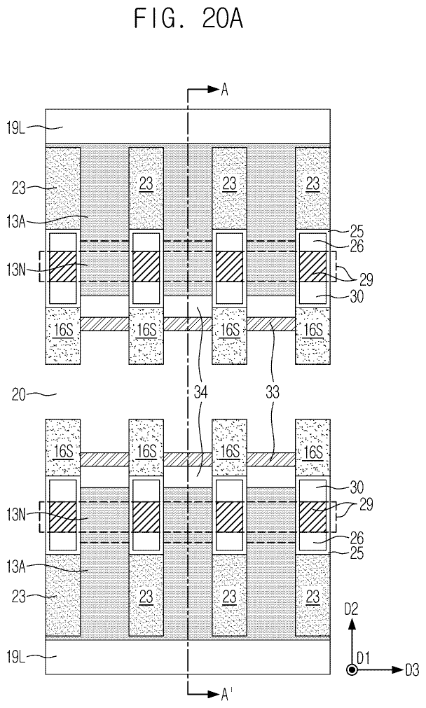

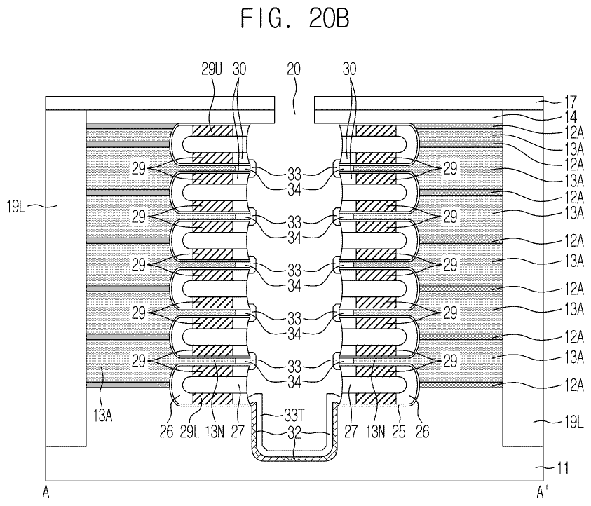

FIG. 20A is a plan view illustrating the structure at the narrow sheet level to describe a method for forming first contact nodes 33. FIG. 20B is a cross-sectional view of the structure taken along line A-A′ illustrated in FIG. 20A.

Referring to FIGS. 20A and 20B, the first contact nodes 33 may be selectively formed from the edges E2 of the narrow sheets 13N. The first contact nodes 33 may be formed through selective epitaxial growth (SEG). The first contact nodes 33 may be epitaxial layers of a silicon layer. The first contact nodes 33 may be doped silicon epitaxial layers. The first contact nodes 33 may be silicon epitaxial layers doped with N-type impurities. The first contact nodes 33 may correspond to the first contact node BLC illustrated in FIGS. 4A to 4C.

First doped regions 34 may be formed within one side of the narrow sheets 13N. A heat treatment process may be performed to form the first doped regions 34, and thus dopants may be diffused from the first contact nodes 33.

While the first contact nodes 33 are formed, a dummy contact node 33T may be formed on the sacrificial protection layer 32. The dummy contact node 33T may be formed through the SEG. The dummy contact node 33T may be an epitaxial layer of a silicon layer. The dummy contact node 33T may be a doped silicon epitaxial layer.

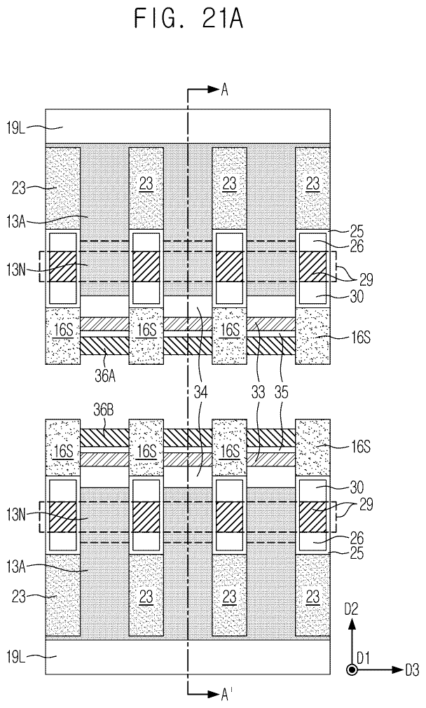

FIG. 21A is a plan view illustrating the structure at a nano sheet level to describe a method for forming first and second vertical conductive lines 36A and 36B. FIG. 21B is a cross-sectional view of the structure taken along line A-A′ illustrated in FIG. 21A.

Referring to FIGS. 21A and 21B, the first and second vertical conductive lines 36A and 36B may be formed on the first contact nodes 33. Before the first and second vertical conductive lines 36A and 36B are formed, ohmic contact layers 35 may be formed on the first contact nodes 33. The ohmic contact layers 35 may each include metal silicide such as titanium silicide or molybdenum silicide. While the ohmic contact layers 35 are formed, a dummy ohmic contact layer 35T may be formed on the dummy contact node 33T.

Forming the first and second vertical conductive lines 36A and 36B may include depositing a metal material and etching the metal material. Etching the metal material may include an etch-back process. For example, the etch-back process of the metal material may be performed without a mask, and the first and second vertical conductive lines 36A and 36B that are isolated from each other may be formed. The first and second vertical conductive lines 36A and 36B adjacent to each other in the third direction D3 may be self-aligned with the supporters 16S. Because the supporters 16S serve as an etch barrier, the first and second vertical conductive lines 36A and 36B may be formed only by the etch-back process. Bottom portions of the first and second vertical conductive lines 36A and 36B adjacent to each other in the second direction D2 may be isolated from each other.

The first and second vertical conductive lines 36A and 36B may be vertically oriented in the first direction D1. The first and second vertical conductive lines 36A and 36B may each include a bit line. The first and second vertical conductive lines 36A and 36B may each include metal, a metal-based material, or a combination thereof. The first and second vertical conductive lines 36A and 36B may each include metal, metal nitride, metal silicide, or a combination thereof. The first and second vertical conductive lines 36A and 36B may each include titanium nitride, tungsten, or a combination thereof. For example, the first and second vertical conductive lines 36A and 36B may include a titanium nitride/tungsten (TiN/W) stack in which titanium nitride and tungsten are sequentially stacked. The first and second vertical conductive lines 36A and 36B may correspond to the first conductive lines BL illustrated in FIGS. 4A to 4D.

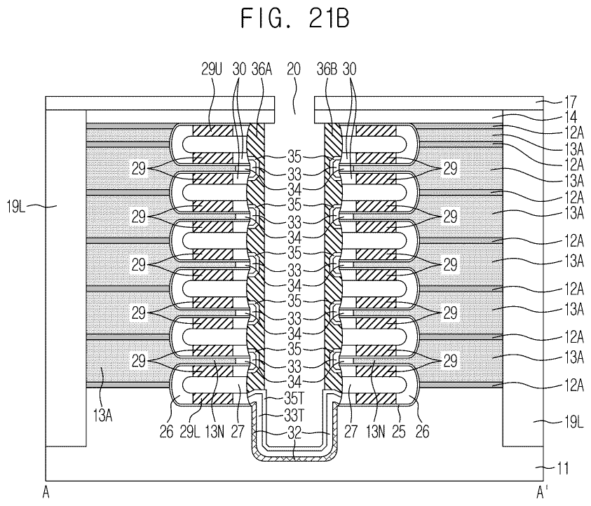

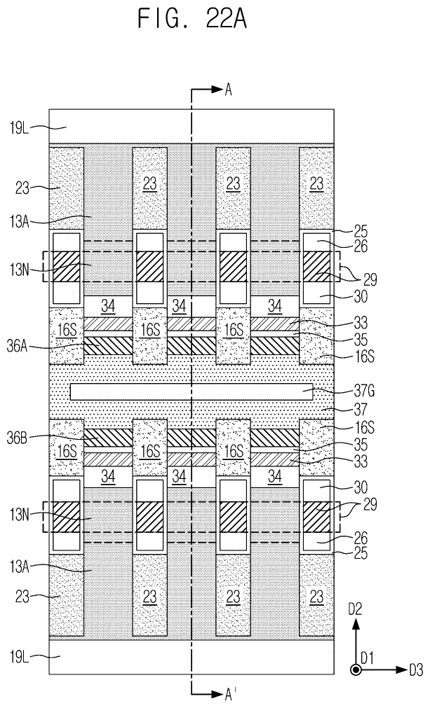

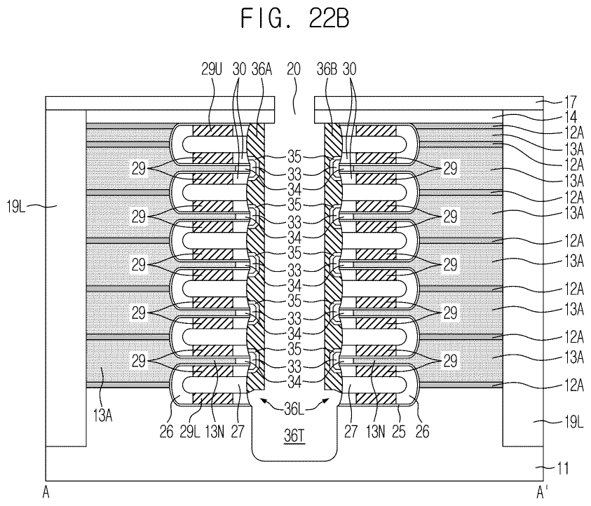

FIG. 22A is a plan view illustrating the structure at the nano sheet level to describe a method for forming an array isolation layer 37. FIGS. 22B and 22C are cross-sectional views of the structure taken along line A-A′ illustrated in FIG. 22A.

Referring to FIGS. 22A and 22B, the sacrificial protection layer 32, the dummy contact node 33T and the dummy ohmic contact layer 35T may be selectively removed. Accordingly, a bottom trench 36T may be formed between the bottom portions of the first and second vertical conductive lines 36A and 36B and the substrate 11. The bottom trench 36T may include bridge preventing spaces 36L. Sizes of the bridge preventing spaces 36L may be equal to the total thickness of the sacrificial protection layer 32, the dummy contact node 33T and the dummy ohmic contact layer 35T. The bottom portions of the first and second vertical conductive lines 36A and 36B may be spaced apart from the surface of the substrate 11 by the bridge preventing spaces 36L. That is, the bridge preventing spaces 36L may prevent bridging between the bottom portions of the first and second vertical conductive lines 36A and 36B and the substrate 11. Although the bottom portions of the first and second vertical conductive lines 36A and 36B are close to the substrate 11, the bridge preventing spaces 36L may prevent the bridging between the bottom portions of the first and second vertical conductive lines 36A and 36B and the substrate 11. Because heights of the bridge preventing spaces 36L are small, the bottom portions of the first and second vertical conductive lines 36A and 36B may be formed close to the substrate 11.

Referring to FIG. 22C, the array isolation layer 37 may be formed between the first vertical conductive line 36A and the second vertical conductive line 36B. The array isolation layer 37 may include a dielectric material. The array isolation layer 37 may include an air gap 37G and bridge preventing portions 37B. The array isolation layer 37 may fill a space between the first vertical conductive lines 36A horizontally adjacent to each other and a space between the second vertical conductive lines 36B horizontally adjacent to each other. The array isolation layer 37 may fill the bottom trench 36T. The bridge preventing portions 37B may fill the bridge preventing spaces 36L. The array isolation layer 37 may include a dielectric material. The array isolation layer 37 may include spin-on-dielectric (SOD), silicon oxide, silicon nitride, or a combination thereof.

Forming the array isolation layer 37 may include depositing a dielectric material and planarizing the dielectric material. The air gap 37G may be formed during the deposition of the dielectric material.

As described above, the bottom portions of the first and second vertical conductive lines 36A and 36B may be spaced apart from the surface of the substrate 11 by the total thickness of the sacrificial protection layer 32, the dummy contact node 33T and the dummy ohmic contact layer 35T. That is, the bridging between the bottom portions of the first and second vertical conductive lines 36A and 36B and the substrate 11 may be prevented by the bridge preventing portions 37B of the array isolation layer 37. Although the bottom portions of the first and second vertical conductive lines 36A and 36B are close to the substrate 11, the bridge preventing portions 37B of the array isolation layer 37 may prevent the bridging between the bottom portions of the first and second vertical conductive lines 36A and 36B and the substrate 11. Because heights of the bridge preventing portions 37B are small, the bottom portions of the first and second vertical conductive lines 36A and 36B may be formed close to the substrate 11.

In an embodiment, dummy memory cells may not be formed because the bottom portions of the first and second vertical conductive lines 36A and 36B are formed close to the substrate 11. Because the dummy memory cells are not present, memory cell density may be increased.

In a comparative example, oxide gap-fill and etch-back processes may be performed before the forming of the first and second vertical conductive lines 36A and 36B. Oxide remaining after the oxide etch-back process may block a bridge pass between the first and second vertical conductive lines 36A and 36B and the substrate 11.

However, the comparative example has a problem in that an end point of the etch-back process has to be set much higher than the surface of the substrate 11 because of large variations in the oxide etch-back process. Consequently, in the comparative example, a plurality of dummy memory cells in which first and second vertical conductive lines are not formed may be formed, and thus memory cell density may decrease.

In an embodiment, through the growth and removal process of the sacrificial protection layer 32, it is possible to suppress dummy memory cells and (for example, easily or controllably) isolate the first and second vertical conductive lines 36A and 36B.

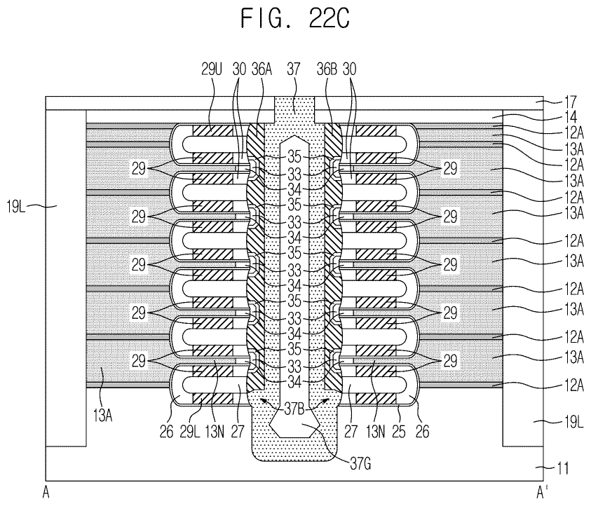

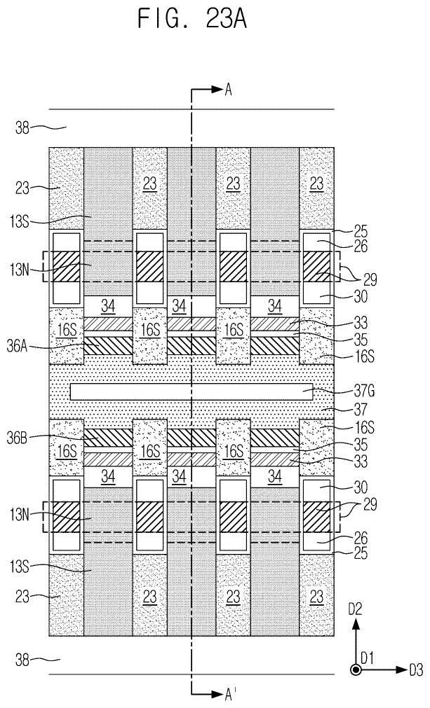

FIG. 23A is a plan view illustrating the structure at the narrow sheet level to describe a method for forming second linear openings 38. FIG. 23B is a cross-sectional view of the structure taken along line A-A′ illustrated in FIG. 23A.

Referring to FIGS. 23A and 23B, the second linear sacrificial layer 19L may be selectively removed. Accordingly, the second linear openings 38 may be formed.

After the second linear openings 38 are formed, the first mold layers 12A may be selectively recessed through the second linear openings 38. To selectively recess the first mold layers 12A, a difference in etch selectivity between the first mold layers 12A and the original body portions 13A may be used. The first mold layers 12A may be removed using a wet etch process or a dry etch process. For example, when the first mold layers 12A include silicon germanium layers and the original body portions 13A include monocrystalline silicon layers, the silicon germanium layers may be etched using an etchant or etch gas having a selectivity with respect to the monocrystalline silicon layers.

Subsequently, the original body portions 13A may be recessed. To recess the original body portions 13A, the wet etch process or the dry etch process may be used. Vertical thicknesses of the original body portions 13A may be reduced, as indicated by reference numeral “13S”. Hereinafter, the original body portions having the reduced vertical thicknesses are referred to as “recessed body portions 13S”.

Each of inter-body recesses 39 may be formed between the recessed body portions 13S that are vertically disposed.

FIG. 24A is a plan view illustrating the structure at the narrow sheet level to describe a method for forming nano sheets HL. FIG. 24B is a cross-sectional view of the structure taken along line A-A′ illustrated in FIG. 24A.

Referring to FIGS. 24A and 24B, third inter-cell dielectric layers 40 may be formed to fill the inter-body recesses 39. The third inter-cell dielectric layers 40 may each include silicon oxide.

After the third inter-cell dielectric layers 40 are formed, bottom protection layers 41T may be formed on bottom portions of the second linear openings 38. The bottom protection layers 41T may each include a material having an etch selectivity with respect to the substrate 11. The bottom protection layers 41T may each include a dielectric material. The bottom protection layers 41T may each include silicon oxide, silicon nitride, silicon carbon oxide, or a combination thereof.

After the bottom protection layers 41T are formed, storage openings 41 may be formed by horizontal recessing of the recessed body portions 13S. The storage openings 41 may be referred to as “capacitor openings”. The nano sheets HL may be formed by the horizontal recessing of the recessed body portions 13S. Each of the nano sheets HL may include the narrow sheet 13N and a wide sheet 13W. The narrow sheet 13N may include a first doped region 34. The wide sheet 13W of the nano sheet HL may refer to the recessed body portion 13S remaining after the recessing. An average vertical height of the wide sheets 13W of the nano sheets HL in the first direction D1 may be greater than an average vertical height of the narrow sheets 13N. A thickness of the wide sheet 13W of the nano sheet HL may gradually increase in the second direction D2. A horizontal length of the wide sheet 13W in the second direction D2 may be less than a horizontal length of the narrow sheet 13N. The wide sheet 13W of the nano sheet HL may have a fan-like shape. The wide sheet 13W may be referred to as a “fan-shaped sheet”, and the narrow sheet 13N may be referred to as a “flat plate-shaped sheet”.

To form the nano sheets HL each including the wide sheet 13W, the recessed body portions 13S may be isotropically or anisotropically etched. One side of the wide sheet 13W, i.e., the side exposed by each of the storage openings 41, may have a flat shape. The one side of the wide sheet 13W may have various shapes.

The one side of the wide sheet 13W may have various shapes. For example, the one side of the wide sheet 13W may have a rounded concave shape, a rounded convex shape, an angled concave shape, or an angled convex shape.

The bottom protection layers 41T and a lowermost third inter-cell dielectric layer 40 may prevent loss of the substrate 11 during the recessing process of the recessed body portions 13S.

Each of the storage openings 41 may be disposed between the third inter-cell dielectric layers 40 in the first direction D1.

In some embodiments, the horizontal recessing of the recessed body portions 13S for forming the wide sheets 13W may stop at a boundary area between the narrow sheet 13P and the wide sheet 13W.

The first spacer 26 may surround the wide sheets 13W at the same horizontal level, which are disposed in third direction D3. The second spacer 30 may surround the narrow sheets 13N at the same horizontal level, which are disposed in the third direction D3.

FIG. 25A is a plan view illustrating the structure at the nano sheet level to describe a method for forming the nano sheets HL. FIG. 25B is a cross-sectional view illustrating the structure taken along line A-A′ illustrated in FIG. 25A.

Referring to FIGS. 25A and 25B, a pre-cleaning process may be performed on the surfaces of the wide sheets 13W.

Second contact nodes 42 may be formed on the wide sheets 13W. Forming the second contact nodes 42 may include selective epitaxial growth (SEG). For example, a semiconductive material may be grown from the side surfaces of the wide sheets 13W through the SEG. The second contact nodes 42 may each include SEG Si. Because the wide sheets 13W each include monocrystalline silicon, a silicon layer may be epitaxially grown along crystal surfaces of the side surfaces of the wide sheets 13W.

The second contact nodes 42 may each include a dopant. When the silicon layer is grown using the SEG, dopants may be doped in situ. Accordingly, the second contact nodes 42 may each be a doped epitaxial layer. The second contact nodes 42 may each include an N-type dopant as the dopant. The N-type dopant may include phosphorus, arsenic, antimony, or a combination thereof. The second contact nodes 42 may each include a phosphorus-doped silicon epitaxial layer formed by the SEG, i.e., a doped SEG SiP. In some embodiments, the second contact nodes 42 may be formed through deposition and etch-back processes of doped polysilicon.

Each of the second contact nodes 42 may be disposed between the third inter-cell dielectric layers 40 that are vertically stacked. The second contact nodes 42 may correspond to the second contact node SNC illustrated in FIGS. 4A to 4C.

Second doped regions 43 may be formed in the wide sheets 13W. A heat treatment process may be performed to form the second doped regions 43, and thus dopants may be diffused from the second contact nodes 42.

A channel 44 may be defined between the first doped region 34 and the second doped region 43. A horizontal arrangement of the first doped region 34, the channel 44 and the second doped region 43 may form each of the nano sheets HL.

Each of the nano sheets HL may include the first doped region 34, the second doped region 43, and the channel 44. The first doped region 34 and the channel 44 may be formed in the narrow sheet 13N. The second doped region 43 may be formed in the wide sheet 13W. A portion of each of the second doped regions 43 may extend into the narrow sheets 13N. One side of each of the second doped regions 43 of the nano sheets HL may be coupled to the channel 44. The other side of each of the second doped regions 43 of the nano sheets HL may be coupled to the second contact nodes 42. The first doped region 34, the second doped region 43 and the channel 44 may correspond to the first doped region SR, the second doped region DR and the channel CH illustrated in FIGS. 4A to 4C, respectively. The nano sheet HL, the nano sheet dielectric layer 25 and the horizontal conductive line 29 may be a switching element.

The first spacer 26 may surround the second doped regions 43 at the same horizontal level, which are disposed in the third direction D3. The second spacer 30 may surround the first doped regions 34 at the same horizontal level, which are disposed in the third direction D3. The horizontal conductive line 29 may surround the channels 44 at the same horizontal level, which are disposed in the third direction D3.

In some embodiments, an ohmic contact layer including metal silicide may be further formed after the second contact nodes 42 are formed.

As described above, the nano sheets HL may be formed by subsequent selective recessing processes performed on the second mold layers 13 of the mold stack SB, and each of the nano sheets HL may include the narrow sheet 13N and the wide sheet 13W. The first doped regions 34 and the channels 44 may be formed in the narrow sheets 13N, and the second doped regions 43 may be formed in the wide sheets 13W.

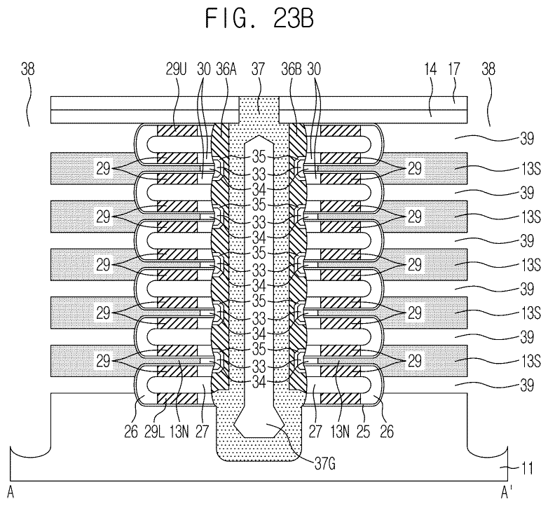

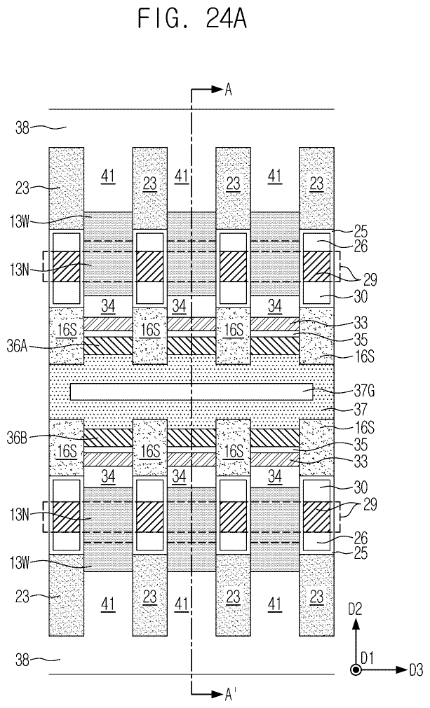

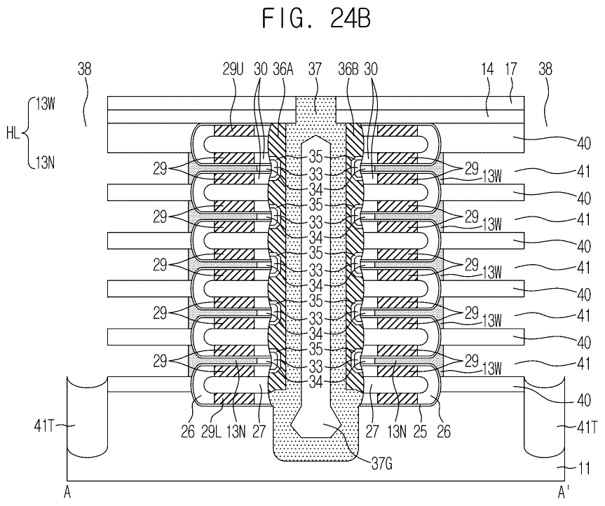

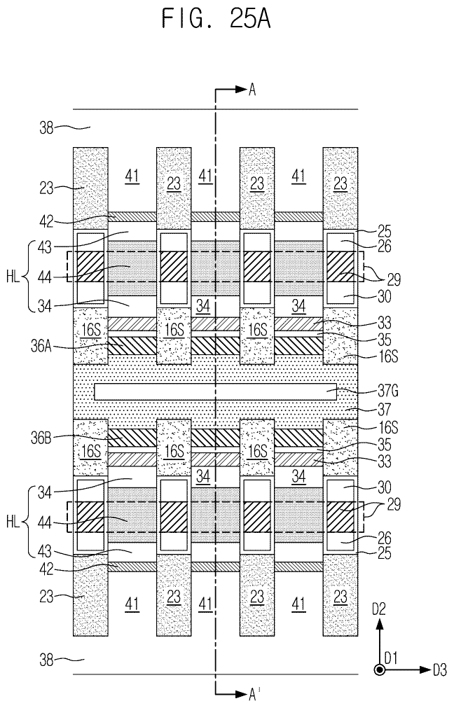

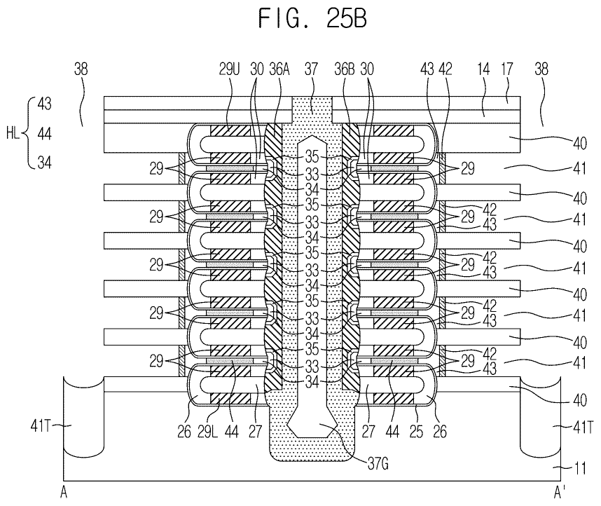

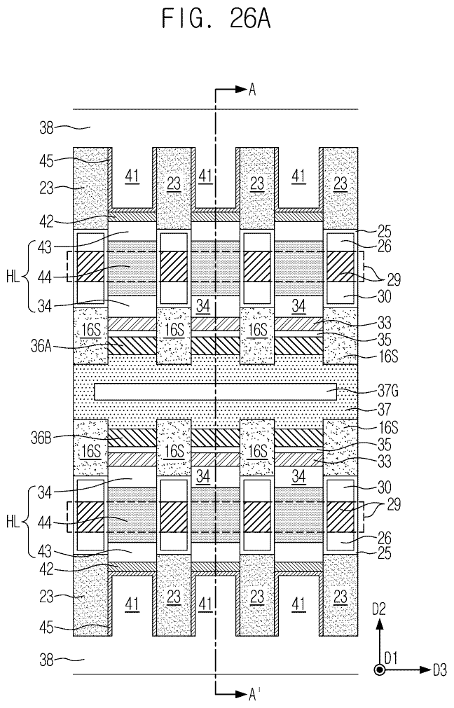

FIG. 26A is a plan view illustrating the structure at the narrow sheet level to describe a method for forming first electrodes 45. FIG. 26B is a cross-sectional view illustrating the structure taken along line A-A′ illustrated in FIG. 26A.

Referring to FIGS. 26A and 26B, the first electrodes 45 of a data storage element may be formed on the second contact nodes 42. The first electrodes 45 may each have a horizontally-oriented cylindrical shape. Each of the first electrodes 45 may be disposed in a different one of the storage openings 41. The first electrodes 45 disposed adjacent to each other in the second direction D2 may be spaced apart from each other by the second linear openings 38. The first electrodes 45 disposed adjacent to each other in the first direction D1 may be spaced apart from each other by the third inter-cell dielectric layers 40. Forming the first electrodes 45 may include depositing a metal material, gap-filling a sacrificial material, and isolating the metal material in a vertical/horizontal direction. The sacrificial material may include oxide or polysilicon.

Each of the first electrodes 45 may include an inner space and a plurality of outer surfaces. The inner space of the first electrode 45 may include a plurality of inner surfaces. The outer surfaces of the first electrode 45 may include a vertical outer surface and a plurality of horizontal outer surfaces. The vertical outer surface of the first electrode 45 may vertically extend in the first direction D1. The horizontal outer surfaces of the first electrode 45 may horizontally extend in the second direction D2 or the third direction D3. The inner space of the first electrode 45 may be a three-dimensional space. The first electrode 45 may have a cylindrical shape.

Among the outer surfaces of the first electrode 45, the vertical outer surface may be electrically coupled to the nano sheet HL and the second contact node 42.

The first electrode 45 may include metal, noble metal, metal nitride, conductive metal oxide, conductive noble metal oxide, metal carbide, metal silicide, or a combination thereof. For example, the first electrode 45 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

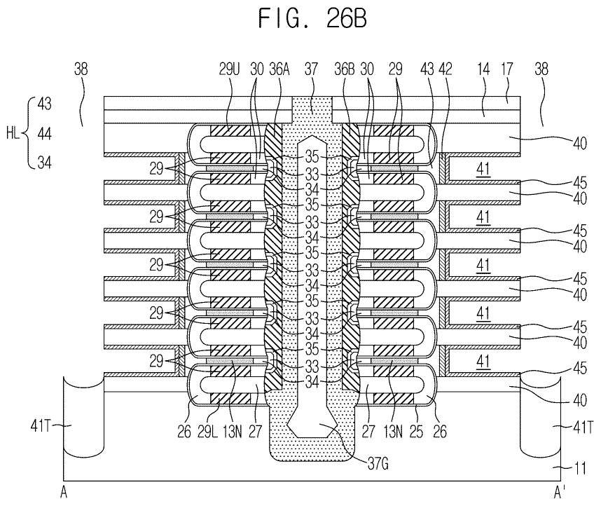

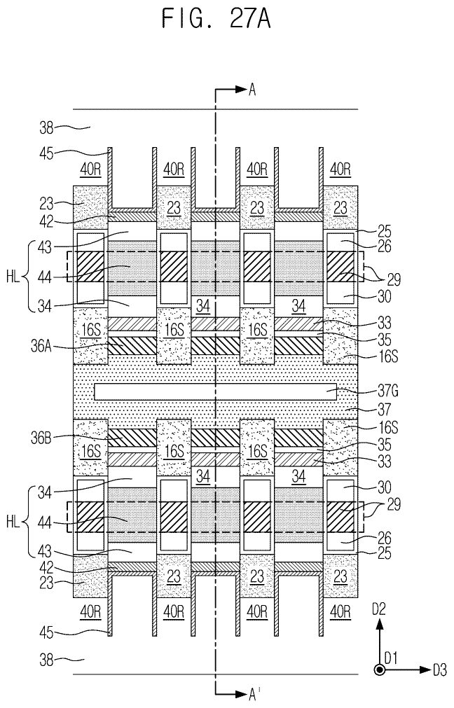

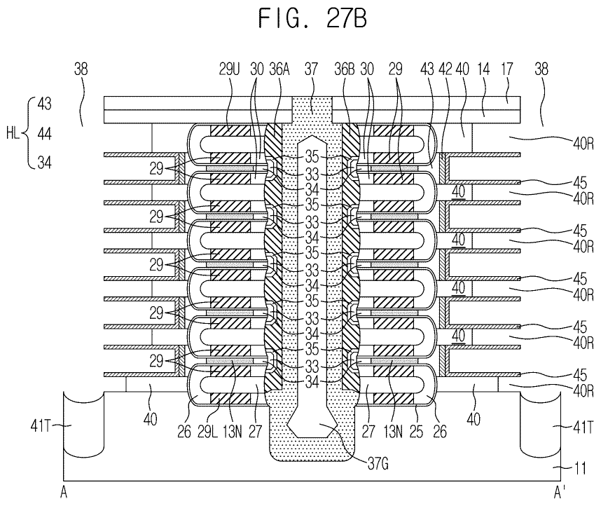

FIG. 27A is a plan view illustrating the structure at the narrow sheet level to describe a method for partially recessing the third inter-cell dielectric layers 40. FIG. 27B is a cross-sectional view of the structure taken along line A-A′ illustrated in FIG. 27A.

Referring to FIGS. 27A and 27B, portions of the first and third inter-cell dielectric layers 23 and 40 may be horizontally recessed (refer to reference numeral “40R”). Accordingly, outer walls of the first electrodes 45 may be partially exposed. The first electrodes 45 may each have a semi-cylindrical shape. Horizontal recess depths of the third inter-cell dielectric layers 40 may be depths that do not expose the second contact nodes 42. The semi-cylindrical shape of each of the first electrodes 45 may include cylindrical inner surfaces and semi-cylindrical outer surfaces.

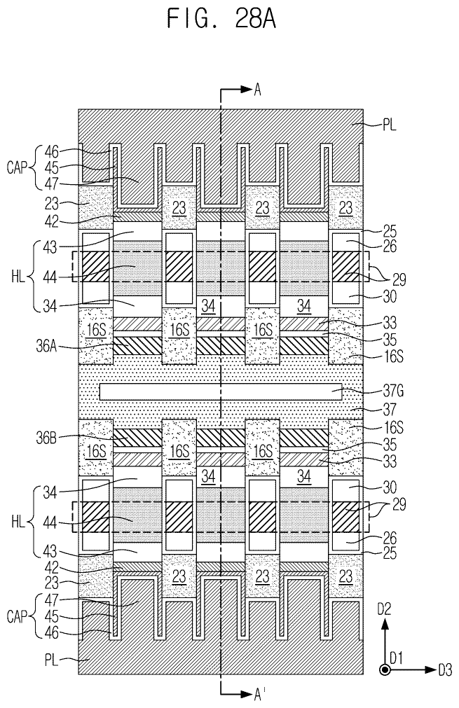

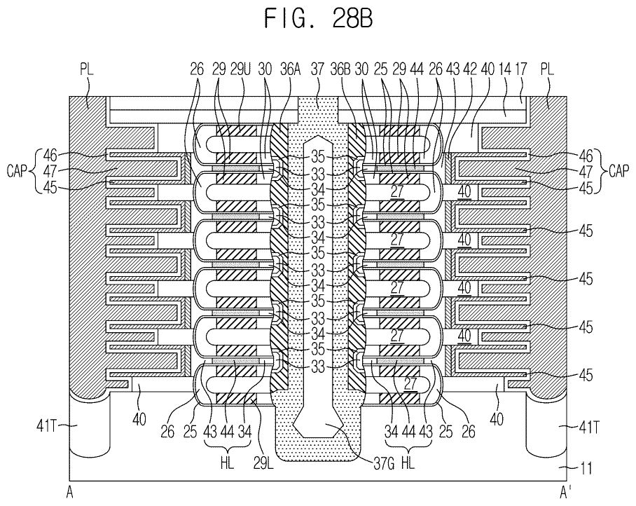

FIG. 28A is a plan view illustrating the structure at the narrow sheet level to describe a method for forming a second electrode 47. FIG. 28B is a cross-sectional view of the structure taken along line A-A′ illustrated in FIG. 28A.

Referring to FIGS. 28A and 28B, a dielectric layer 46 and the second electrode 47 may be sequentially formed on the first electrodes 45. The first electrode 45, the dielectric layer 46 and the second electrode 47 may be the data storage element CAP. The second electrodes 47 of the data storage elements CAP may be merged with one another and form a common plate PL.

The dielectric layer 46 and the second electrode 47 may be disposed on the cylindrical inner surfaces of the first electrode 45. A portion of the dielectric layer 46 and a portion of the second electrode 47 may extend to be disposed on the semi-cylindrical outer surfaces of the first electrode 45. The second electrode 47 may vertically extend in the first direction D1.

The dielectric layer 46 may be referred to as a “capacitor dielectric layer” or a “memory layer”. The dielectric layer 46 may include silicon oxide, silicon nitride, a high-k material, a ferroelectric material, an antiferroelectric material, a perovskite material, or a combination thereof. The dielectric layer 46 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 46 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a ZHZAZHZA (ZrO₂/HfO₂/ZrO₂/Al₂O₃/ZrO₂/HfO₂/ZrO₂/Al₂O₃) stack, a ZHZAZHZAT (ZrO₂/HfO₂/ZrO₂/Al₂O₃/ZrO₂/HfO₂/ZrO₂/Al₂O₃/TiO₂) stack, a HZHZ (HfO₂/ZrO₂/HfO₂/ZrO₂) stack, or an AHZAZHA (Al₂O₃/HfO₂/ZrO₂/Al₂O₃/ZrO₂/HfO₂/Al₂O₃) stack.

The second electrode 47 may include metal, noble metal, metal nitride, conductive metal oxide, conductive noble metal oxide, metal carbide, metal silicide, or a combination thereof. For example, the second electrode 47 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The titanium silicon nitride/titanium nitride/tungsten (TiSiN/TiN/W) stack may refer to a structure in which titanium silicon nitride, titanium nitride and tungsten are sequentially stacked. The second electrode 47 may also include a combination of a metal-based material and a silicon-based material. For example, a titanium nitride, tungsten and polysilicon may be sequentially stacked in the second electrode 47.

In some embodiments, the data storage element CAP may further include a plurality of interface control layers to alleviate leakage current. Each of the interface control layers may include titanium oxide (TiO₂), tantalum oxide (Ta₂O₅), niobium oxide (Nb₂O₅), niobium nitride (NbN), niobium oxynitride (NbON), or a combination thereof. A first interface control layer may be formed between the first electrode 45 and the dielectric layer 46, and a second interface control layer may be formed between the dielectric layer 46 and the second electrode 47. For example, a structure in which the first interface control layer, the dielectric layer 46 and the second interface control layer are sequentially stacked may include an NZHZAZHZATN (Nb₂O₅/ZrO₂/HfO₂/ZrO₂/Al₂O₃/ZrO₂/HfO₂/ZrO₂/Al₂O₃/TiO₂/Nb₂O₅) stack.

In some embodiments, the recessing of the third and first inter-cell dielectric layers 40 and 23 illustrated in FIG. 27B may be omitted. Thereafter, as illustrated in FIG. 28B, the dielectric layer 46 and the second electrode 47 may be formed. Accordingly, the data storage element CAP including the concave-shaped first electrode 45 may be formed.

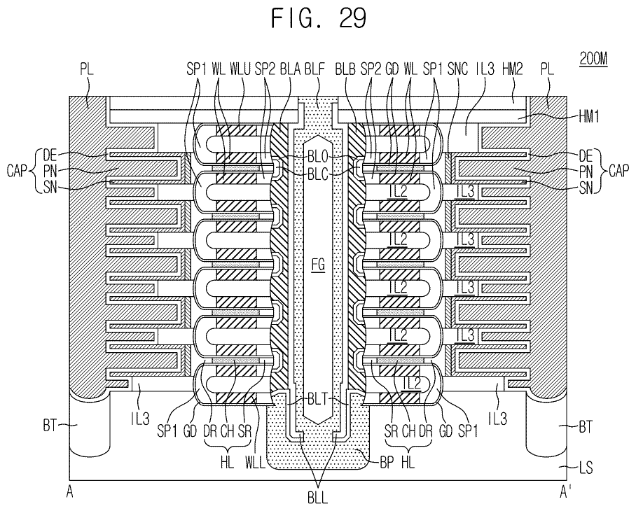

FIG. 29 is a schematic cross-sectional view of a semiconductor device 200M in accordance with an embodiment of the present disclosure. FIG. 29 may be the schematic cross-sectional view of the semiconductor device 100 taken along line A-A′ illustrated in FIG. 4A. The semiconductor device 200M may be similar to the semiconductor device 100 illustrated in FIGS. 4A to 4D. Detailed descriptions of overlapping components are provided above with reference to FIGS. 4A to 4D.

Referring to FIG. 29, the semiconductor device 200M may include a first vertical conductive line BLA and a second vertical conductive line BLB. An array isolation layer BLF may be disposed between the first vertical conductive line BLA and the second vertical conductive line BLB. The array isolation layer BLF may include a dielectric material. The first vertical conductive lines BLA and the second vertical conductive lines BLB, which are adjacent to each other in a second direction D2, may be isolated from each other by the array isolation layer BLF.

A vertical spacer BLL may be disposed between the array isolation layer BLF and the first and second vertical conductive lines BLA and BLB. A dummy ohmic contact layer BLT may be coupled to bottom portions of the first and second vertical conductive lines BLA and BLB. A bottom portion of the vertical spacer BLL may extend downward to cover the dummy ohmic contact layer BLT.

The array isolation layer BLF may include an air gap FG and bridge preventing portions BP. The air gap FG may reduce parasitic capacitance between the first vertical conductive line BLA and the second vertical conductive line BLB adjacent to each other. The bridge preventing portions BP of the array isolation layer BLF may prevent bridging between the bottom portions of the first and second vertical conductive lines BLA and BLB and a lower structure LS. Although the bottom portions of the first and second vertical conductive lines BLA and BLB are close to the lower structure LS, the bridge preventing portions BP of the array isolation layer BLF may prevent the bridging between the bottom portions of the first and second vertical conductive lines BLA and BLB and the lower structure LS. Because heights of the bridge preventing portions BP are small, the bottom portions of the first and second vertical conductive lines BLA and BLB may be formed close to the lower structure LS.

In an embodiment, because the bottom portions of the first and second vertical conductive lines BLA and BLB are formed close to the lower structure LS, dummy memory cells may not be generated. Because the dummy memory cells are not present, it is possible to increase memory cell density.

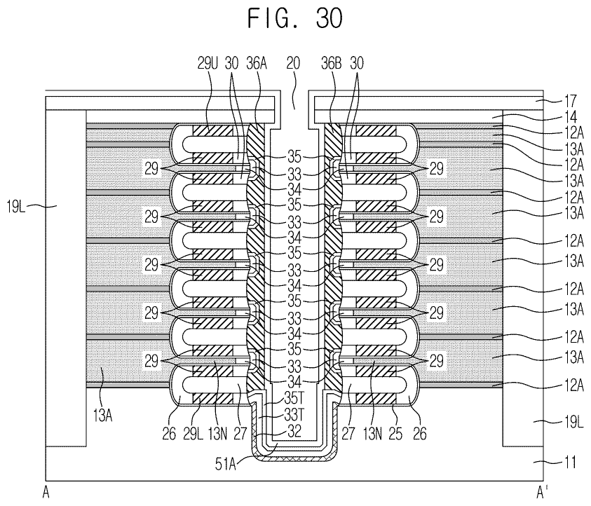

FIGS. 30 to 34 illustrate various views of the semiconductor device 200M formed utilizing a method for fabricating the semiconductor device 200M illustrated in FIG. 29.

As described with reference to FIGS. 5A to 21B, a sacrificial protection layer 32, a dummy contact node 33T, a dummy ohmic contact layer 35T and first and second vertical conductive lines 36A and 36B may be formed.

Subsequently, referring to FIG. 30, a vertical liner layer 51A may be formed. The vertical liner layer 51A may be conformally formed on the first and second vertical conductive lines 36A and 36B. The vertical liner layer 51A may include silicon oxide.

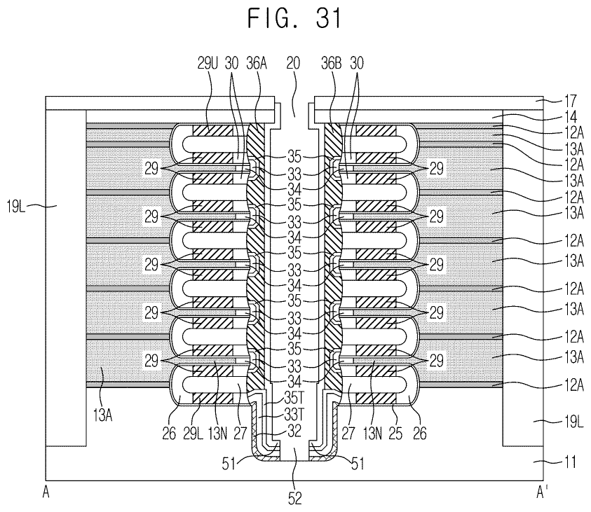

Referring to FIG. 31, the vertical liner layer 51A may be etched to form a vertical spacer 51. The dummy ohmic contact layer 35T may be exposed below a bottom portion of the vertical spacer 51.

The dummy ohmic contact layer 35T, the dummy contact node 33T and the sacrificial protection layer 32 may be sequentially cut using the vertical spacer 51 as an etch barrier. Accordingly, a bottom isolation trench 52 may be formed.

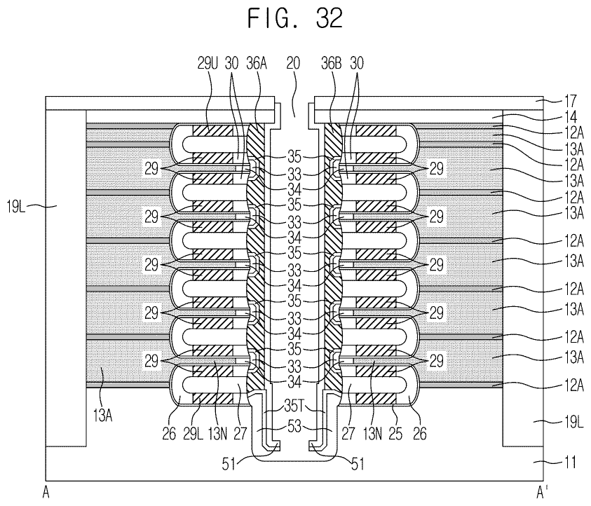

Referring to FIG. 32, the dummy contact node 33T and the sacrificial protection layer 32 may be sequentially removed through the bottom isolation trench 52. While the dummy contact node 33T and the sacrificial protection layer 32 are removed, the dummy ohmic contact layer 35T and the vertical spacer 51 may serve as an etch barrier.

A bottom trench 53 may be formed in a spacer where the dummy contact node 33T and the sacrificial protection layer 32 is removed. The bottom trench 53 may expose a surface of a substrate 11. The bottom trench 53 may have a U shape.

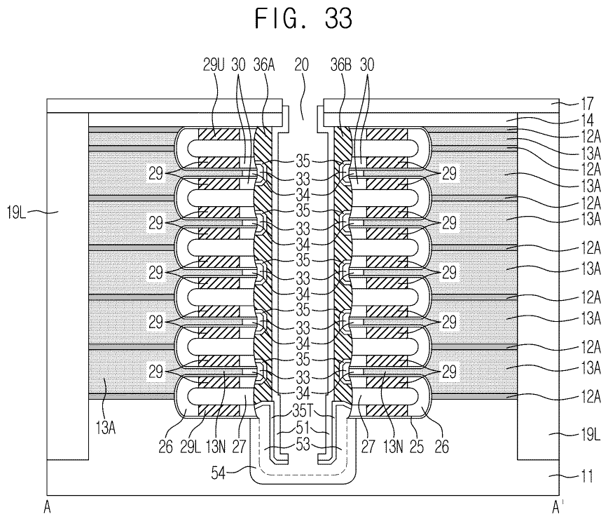

Referring to FIG. 33, the surface of the substrate 11 exposed by the bottom trench 53 may be trimmed. Accordingly, a substrate trimming portion 54 may be formed. The substrate trimming portion 54 may have a U shape.

As described above, the bottom trench 53 and the substrate trimming portion 54 may be formed between the bottom portions of the first and second vertical conductive lines 36A and 36B and the substrate 11.

The bottom portions of the first and second vertical conductive lines 36A and 36B and the surface of the substrate 11 may be spaced apart from each other by the bottom trench 53 and the substrate trimming portion 54. That is, bridging between the bottom portions of the first and second vertical conductive lines 36A and 36B and the substrate 11 may be prevented by the bottom trench 53 and the substrate trimming portion 54. Although the bottom portions of the first and second vertical conductive lines 36A and 36B are close to the substrate 11, the bridging between the bottom portions of the first and second vertical conductive lines 36A and 36B and the substrate 11 may be prevented by the bottom trench 53 and the substrate trimming portion 54. Because heights of the bottom trench 53 and the substrate trimming portion 54 is small, the bottom portions of the first and second vertical conductive lines 36A and 36B may be formed close to the substrate 11.

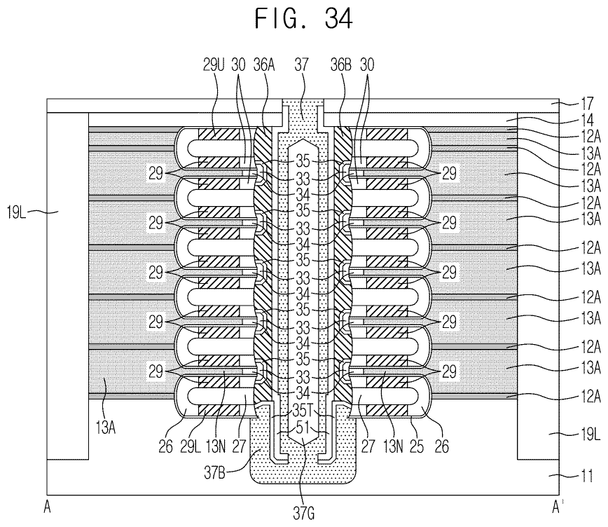

Referring to FIG. 34, an array isolation layer 37 may be formed between the first and second vertical conductive lines 36A and 36B. The array isolation layer 37 may include a dielectric material. The array isolation layer 37 may include an air gap 37G and bridge preventing portions 37B. The array isolation layer 37 may fill a space between the first and second vertical conductive lines 36A and 36B. The array isolation layer 37 may fill a first linear opening 20, the bottom trench 53 and the substrate trimming portion 54. The bridge preventing portions 37B may fill the bottom trench 53 and the substrate trimming portion 54. The array isolation layer 37 may include silicon oxide.

The vertical spacer 51 may be disposed between the array isolation layer 37 and the first and second vertical conductive lines 36A and 36B. The dummy ohmic contact layer 35T may be coupled to the bottom portions of the first and second vertical conductive lines 36A and 36B. The bottom portion of the vertical spacer 51 may extend downward to cover the dummy ohmic contact layer 35T.

Forming the array isolation layer 37 may include depositing a dielectric material and planarizing the dielectric material. The air gap 37G may be formed during the deposition of the dielectric material.

As described above, the bottom portions of the first and second vertical conductive lines 36A and 36B may be spaced apart from the surface of the substrate 11 by the total thickness of the bottom trench 53 and the substrate trimming portion 54. That is, the bridge preventing portions 37B of the array isolation layer 37 may prevent the bridging between the bottom portions of the first and second vertical conductive lines 36A and 36B and the substrate 11. Although the bottom portions of the first and second vertical conductive lines 36A and 36B are close to the substrate 11, the bridge preventing portions 37B of the array isolation layer 37 may prevent the bridging between the bottom portions of the first and second vertical conductive lines 36A and 36B and the substrate 11. Because heights of the bridge preventing portions 37B are small, the bottom portions of the first and second vertical conductive lines 36A and 36B may be formed close to the substrate 11.

In an embodiment, dummy memory cells may not be generated because the bottom portions of the first and second vertical conductive lines 36A and 36B are formed close to the substrate 11. Because the dummy memory cells are not present, this provides the capability to increase memory cell density.

Subsequently, a wide sheet, a second contact node, a nano sheet and data storage elements may be formed through a series of processes as described with reference to FIGS 23a to 28b.

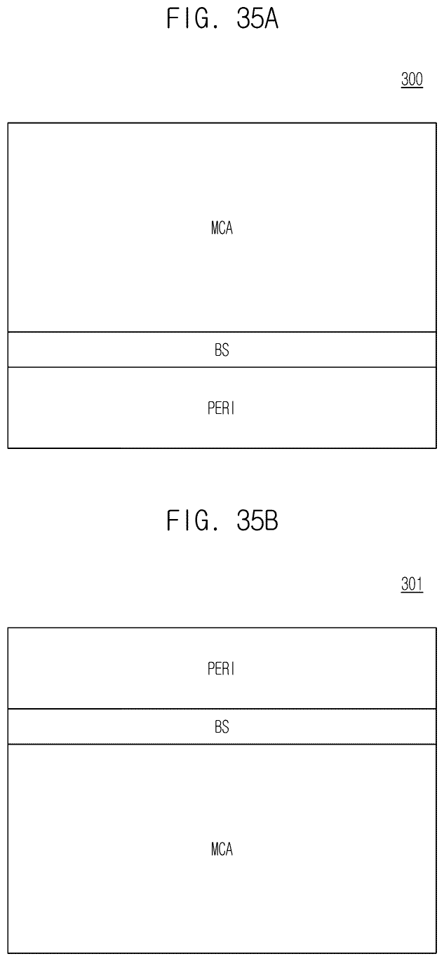

FIGS. 35A and 35B are schematic cross-sectional views of semiconductor devices 300 and 301 in accordance with embodiments of the present disclosure.

Referring to FIG. 35A, the semiconductor device 300 may include a memory cell array MCA, a peripheral circuit portion PERI, and a bonding interface BS. The bonding interface BS may be disposed between the memory cell array MCA and the peripheral circuit portion PERI. In the semiconductor device 300, the memory cell array MCA may be disposed at a level higher than the peripheral circuit portion PERI. The semiconductor device 300 may be referred to as a “Peri Under Cell array (PUC) structure”. The memory cell array MCA may include a substrate on which back-grinding is performed and an array of memory cells. For example, as described with reference to FIG. 34, after the data storage element CAP is formed, the substrate 11 may be flipped over through wafer-flipping, and then a back side of the substrate 11 may be partially ground.

Referring to FIG. 35B, the semiconductor device 301 may include a memory cell array MCA, a peripheral circuit portion PERI, and a bonding interface BS. The bonding interface BS may be disposed between the memory cell array MCA and the peripheral circuit portion PERI. In the semiconductor device 301, the memory cell array MCA may be disposed at a level lower than the peripheral circuit portion PERI. The semiconductor device 301 may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 35A and FIG. 35B, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for the memory cell array MCA, forming a peripheral circuit bonding pad for the peripheral circuit portion PERI, performing the wafer-flipping so that the cell bonding pad and the peripheral circuit bonding pad face each other, and performing wafer bonding.

The semiconductor device 300 illustrated in FIG. 35A may perform the wafer-flipping on the substrate on which the memory cell array is formed so that the cell bonding pad and the peripheral circuit bonding pad face each other, after the cell bonding pad and the peripheral circuit bonding pad are formed. The semiconductor device 301 illustrated in FIG. 35B may perform the wafer-flipping on the substrate on which the peripheral circuit portion is formed so that the cell bonding pad and the peripheral circuit bonding pad face each other, after the cell bonding pad and the peripheral circuit bonding pad are formed.

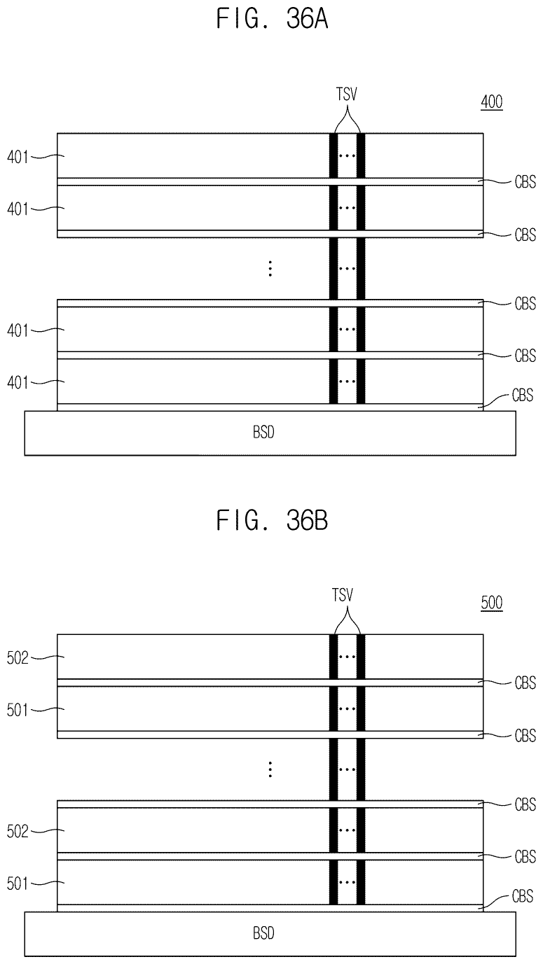

FIGS. 36A and 36B illustrate various views illustrating stack assemblies 400 and 500 in accordance with embodiments of the present disclosure.

Referring to FIG. 36A, the stack assembly 400 may include an assembly of semiconductor dies. For example, the stack assembly 400 may include a first semiconductor die BSD and a plurality of second semiconductor dies 401. The first semiconductor die BSD may include logic circuits. Each of the second semiconductor dies 401 may include memory cell arrays according to embodiments described above.

Each of the second semiconductor dies 401 may include structures in which a memory cell array stack and a peripheral circuit portion are stacked, for example, the semiconductor device 300 illustrated in FIG. 35A or the semiconductor device 301 illustrated in FIG. 35B. The logic circuits of the first semiconductor die BSD may be different from the peripheral circuit portions of the second semiconductor dies 401. The second semiconductor dies 401 may be at a chip level or a wafer level.

The second semiconductor dies 401 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second semiconductor dies 401 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

Referring to FIG. 36B, the stack assembly 500 may include an assembly of semiconductor dies. For example, the stack assembly 500 may include a first semiconductor die BSD, a plurality of second semiconductor dies 501, and a plurality of third semiconductor dies 502. The first semiconductor die BSD may include logic circuits. Each of the second semiconductor dies 501 and each of the third semiconductor dies 502 may include memory cell array stacks according to embodiments described above. The second semiconductor dies 501 and the third semiconductor dies 502 may have different structures.

Each of the second semiconductor dies 501 may include the semiconductor device 300 illustrated in FIG. 35A in which a memory cell array is stacked over a peripheral circuit portion. Each of the third semiconductor dies 502 may include the semiconductor device 301 illustrated in FIG. 35B in which a peripheral circuit portion is stacked over a memory cell array.

In some embodiments, each of the second semiconductor dies 501 may include the semiconductor device 301 illustrated in FIG. 35B in which a peripheral circuit portion is stacked over a memory cell array, and each of the third semiconductor dies 502 may include the semiconductor device 300 illustrated in FIG. 35A in which a memory cell array is stacked over a peripheral circuit portion.

The logic circuits of the first semiconductor die BSD may be different from the peripheral circuit portions of the second and third semiconductor dies 501 and 502. The second and third semiconductor dies 501 and 502 may be at a chip level or a wafer level.

The second and third semiconductor dies 501 and 502 may be electrically coupled to each other through a plurality of through silicon vias TSV and bonding interfaces CBS. The first semiconductor die BSD and a lowermost second semiconductor die 501 may be electrically coupled to each other through the bonding interface CBS. The second and third semiconductor dies 501 and 502 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

The stack assemblies 400 and 500 described with reference to FIGS. 36A and 36B may be high bandwidth memories.

According to various embodiments of the present disclosure, a bridge preventing portion may prevent bridging between bottom portions of vertical conductive lines and a surface of a substrate.

According to various embodiments of the present disclosure, because bottom portions of vertical conductive lines are formed close to a surface of a substrate, formation of dummy memory cells may be prevented, which makes it possible to increase memory cell density.

According to various embodiments of the present disclosure, because an air gap is formed between neighboring vertical conductive lines, parasitic capacitance between the vertical conductive lines may be reduced.

According to various embodiments of the present disclosure, it is possible to improve reliability of a 3D memory device.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
nano sheets arranged in a vertical arrangement and a horizontal arrangement and spaced apart from a surface of a substrate;
horizontal conductive lines horizontally oriented and disposed to surround the nano sheets arranged in the horizontal arrangement;
vertical conductive lines coupled in common to the nano sheets arranged in the vertical arrangement and respectively coupled to the nano sheets arranged in the horizontal arrangement;
supporters disposed between the vertical conductive lines to support the vertical conductive lines; and
an array isolation layer including bridge preventing portions disposed between bottom portions of the vertical conductive lines and the surface of the substrate.

2. The semiconductor device of claim 1, wherein the bridge preventing portions each include a dielectric material.

3. The semiconductor device of claim 1, wherein the array isolation layer further includes an air gap.

4. The semiconductor device of claim 1, wherein the vertical conductive lines are disposed to be aligned between the supporters.

5. The semiconductor device of claim 1, wherein the supporters each include a dielectric material.

6. The semiconductor device of claim 1, further comprising:
contact nodes disposed between the nano sheets and the vertical conductive lines; and
ohmic contact layers disposed between the contact nodes and the vertical conductive lines.

7. The semiconductor device of claim 6, wherein the contact nodes include doped silicon layers.

8. The semiconductor device of claim 1, further comprising data storage elements each coupled to the nano sheets arranged in the vertical and horizontal arrangements.

9. The semiconductor device of claim 1, further comprising:
a dummy ohmic contact layer disposed to extend from the bottom portions of the vertical conductive lines; and
a vertical spacer disposed to cover the dummy ohmic contact layer and the vertical conductive lines.

10. A semiconductor device comprising:
a first vertical conductive line spaced apart from a surface of a substrate;
a second vertical conductive line horizontally spaced apart from the first vertical conductive line;
first nano sheets arranged in a vertical arrangement coupled in common to the first vertical conductive line;
second nano sheets arranged in a vertical arrangement coupled in common to the second vertical conductive line;
a first horizontal conductive line horizontally oriented and disposed to surround the first nano sheets;
a second horizontal conductive line horizontally oriented and disposed to surround the second nano sheets;
supporters disposed to support the first and second vertical conductive lines; and
an array isolation layer disposed between the first vertical conductive line and the second vertical conductive line, the array isolation layer including bridge preventing portions disposed between bottom portions of the first and second vertical conductive lines and the surface of the substrate.

11. The semiconductor device of claim 10, wherein the bridge preventing portions each include a dielectric material.

12. The semiconductor device of claim 10, wherein the array isolation layer further includes an air gap disposed between the first vertical conductive line and the second vertical conductive line.

13. The semiconductor device of claim 10, wherein the first and second vertical conductive lines are disposed to be aligned with the supporters.

14. The semiconductor device of claim 10, wherein the supporters each include a dielectric material.

15. The semiconductor device of claim 10, further comprising:
first contact nodes disposed between the first nano sheets and the first vertical conductive line and between the second nano sheets and the second vertical conductive line; and
ohmic contact layers disposed between the first contact nodes and the first and second vertical conductive lines.

16. The semiconductor device of claim 15, wherein the first contact nodes include doped silicon layers.

17. The semiconductor device of claim 10, further comprising:
data storage elements each coupled to the first and second nano sheets; and
second contact nodes disposed between the first and second nano sheets and the data storage elements.

18. The semiconductor device of claim 17, wherein each of the first and second nano sheets includes a flat plate-shaped sheet contacting the first and second vertical conductive lines and a fan-shaped sheet contacting the data storage elements.

19. The semiconductor device of claim 10, further comprising:
a dummy ohmic contact layer disposed to extend from the bottom portions of the first and second vertical conductive lines; and
a vertical spacer disposed to cover the dummy ohmic contact layer and the first and second vertical conductive lines.
